(19) United States
(12) Patent Application Publication
(10) Pub. No.: US 2026/0020330 A1
(43) Pub. Date: Jan. 15, 2026

(54) SEMICONDUCTOR DEVICE

(71) Applicant: Samsung Electronics Co., Ltd., Suwon-si (KR)

(72) Inventors: Kwangmuk Lee, Suwon-si (KR); Jung Han Lee, Suwon-si (KR); Byung-Sung Kim, Suwon-si (KR); Jisoo Park, Suwon-si (KR); Kwanyoung Chun, Suwon-si (KR)

(21) Appl. No.: 19/076,346

(22) Filed: Mar. 11, 2025

(30) Foreign Application Priority Data
Jul. 11, 2024 (KR) 10-2024-0091637

(51) Int. Cl. H10D 84/83

(52) U.S. Cl. CPC H10D 84/8316; H10D 84/8312

(57) ABSTRACT

A semiconductor device may include a first active pattern on a substrate, channel patterns on the first active pattern, a gate electrode extending in a first direction on the first active pattern, and a backbone structure extending in a second direction intersecting the first direction. The first active pattern includes a first region and a second region spaced apart in the second direction, the first active pattern includes a first active sidewall in direct contact with the backbone structure and a second active sidewall spaced apart from the first active sidewall in the first direction, and a distance between the first active sidewall and the second active sidewall in the first direction varies as the first active pattern extends from the first region toward the second region.

### CROSS-REFERENCE TO RELATED APPLICATION(S)

This U.S. non-provisional patent application claims priority under 35 U.S.C. § 119 to Korean Patent Application No. 10-2024-0091637 filed on Jul. 11, 2024 in the Korean Intellectual Property Office, the entire contents of which are hereby incorporated by reference.

### BACKGROUND

The inventive concept relates generally to a semiconductor device, and more particularly, relates to a semiconductor device including a field-effect transistor.

A semiconductor device may include an integrated circuit including metal-oxide-semiconductor field-effect transistors (MOSFETs). As sizes and design rules of semiconductor devices have been reduced, sizes of MOSFETs have also been reduced. Operating characteristics of semiconductor devices may be deteriorated by the scale down of the MOSFETs. Thus, various researches are being conducted for semiconductor devices capable of overcoming limitations caused by a high integration density and of improving performance.

### SUMMARY

An object of the inventive concept is to provide a semiconductor device with improved electrical characteristics.

An object of the inventive concept is to provide a semiconductor device with improved integration.

A semiconductor device according to some embodiments of the inventive concept includes a first active pattern on a substrate, channel patterns on the first active pattern, a gate electrode extending in a first direction on the first active pattern, and a backbone structure extending in a second direction intersecting the first direction, wherein the first active pattern includes a first region and a second region spaced apart in the second direction, the first active pattern includes a first active sidewall in direct contact with the backbone structure and a second active sidewall spaced apart from the first active sidewall in the first direction, and a distance between the first active sidewall and the second active sidewall in the first direction is changed from the first region toward the second region.

A semiconductor device according to some embodiments of the inventive concept includes a first active pattern on the substrate, channel patterns on the first active pattern, source/drain patterns electrically connected to the channel patterns, a gate electrode extending in a first direction on the first active pattern, and a backbone structure extending in a second direction intersecting the first direction, wherein the first active pattern includes a first region and a second region spaced apart in the second direction, the first active pattern includes a first active sidewall in direct contact with the backbone structure and a second active sidewall spaced apart from the first active sidewall in the first direction, the second active sidewall includes a first sidewall of the first region, a second sidewall of the second region, and a buffer active sidewall connecting the first sidewall and the second sidewall, a first distance is a distance between the backbone structure and the first sidewall, a second distance is a distance between the backbone structure and the second sidewall, and the buffer active sidewall is configured to change the first distance into the second distance.

A semiconductor device according to some embodiments of the inventive concept includes a substrate including an active pattern, a device isolation layer defining the active pattern, source/drain patterns on the active pattern, channel patterns electrically connected to the source/drain patterns on the active pattern, each of the channel patterns including a plurality of semiconductor patterns vertically stacked and spaced apart from each other, gate electrodes on the channel patterns, respectively, the gate electrodes extending parallel to each other in a first direction, a backbone structure extending in a second direction intersecting the first direction on the device isolation layer, a gate insulating layer between each of the gate electrodes and each of the channel patterns, a gate spacer on a sidewall of each of the gate electrodes, a gate capping pattern on an upper surface of each of the gate electrodes, an interlayer insulating layer on the gate capping pattern, active contacts penetrating (i.e., extending in) the interlayer insulating layer and electrically connected to the source/drain patterns, respectively, gate contacts penetrating the interlayer insulating layer and the gate capping pattern and electrically connected to the gate electrodes, respectively, and a first metal layer on the interlayer insulating layer, the first metal layer including first lines electrically connected to the active contacts and the gate contacts, respectively, wherein the active pattern includes a first region and a second region spaced apart in the second direction, the active pattern includes a first active sidewall in direct contact with the backbone structure and a second active sidewall spaced apart from the first active sidewall in the first direction, and a distance between the first active sidewall and the second active sidewall in the first direction is changed from the first region toward the second region.

### BRIEF DESCRIPTION OF THE DRAWINGS

Example embodiments will be more clearly understood from the following brief description taken in conjunction with the accompanying drawings, wherein like reference numerals (when used) indicate corresponding elements throughout the several views. The accompanying drawings represent non-limiting, example embodiments as described herein.

FIGS. 1 to 3 are conceptual schematic diagrams for illustrating logic cells of a semiconductor device according to embodiments of the inventive concept.

FIG. 4 is a schematic plan view for illustrating a semiconductor device according to embodiments of the inventive concept.

FIGS. 5A to 5F are schematic cross-sectional views taken along lines A-A′, B-B′, C-C′, D-D′, E-E′, and F-F′ of FIG. 4, respectively.

FIG. 6 is a schematic plan view for illustrating a semiconductor device according to an embodiment of the inventive concept.

FIG. 7 is a schematic cross-sectional view taken along line N-N′ of FIG. 5B according to an embodiment of the inventive concept.

FIG. 8A is a schematic plan view for illustrating a semiconductor device according to another embodiment of the inventive concept.

FIG. 8B is a schematic cross-sectional view taken along line N-N′ of FIG. 5B according to another embodiment of the inventive concept.

FIGS. 9 to 17E are schematic views for illustrating intermediate processes in an example method for manufacturing a semiconductor device according to embodiments of the inventive concept.

FIGS. 18 and 19 are schematic plan views for illustrating a semiconductor device according to another embodiment of the inventive concept.

FIG. 20 is a schematic plan view for illustrating another embodiment of the inventive concept.

FIGS. 21A to 21C are schematic cross-sectional views taken along lines A-A′, B-B′, and D-D′ of FIG. 20, respectively, illustrating a semiconductor device according to another embodiment of the inventive concept.

### DETAILED DESCRIPTION

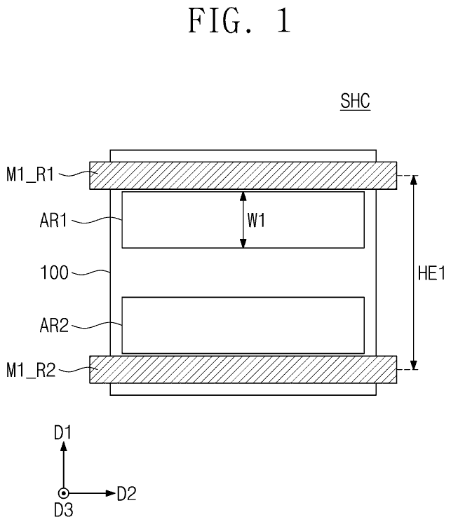

FIGS. 1 to 3 are conceptual schematic diagrams for illustrating logic cells of a semiconductor device according to embodiments of the inventive concept.

Referring to FIG. 1, a single height cell SHC may be provided. In detail, a first power line M1_R1 and a second power line M1_R2 may be provided on a substrate 100. The first power line M1_R1 may be a conduction path, to which a source voltage VSS (e.g., a ground voltage) is provided. The second power line M1_R2 may be a conduction path, to which a drain voltage VDD (e.g., a power voltage) is provided.

The single height cell SHC may be defined between the first power line M1_R1 and the second power line M1_R2. The single height cell SHC may include one first active region AR1 and one second active region AR2. One of the first and second active regions AR1 and AR2 may be a p-channel metal-oxide-semiconductor field-effect transistor (PMOSFET) region, and the other of the first and second active regions AR1 and AR2 may be an n-channel metal-oxide-semiconductor field-effect transistor (NMOSFET) region. That is, the single height cell SHC may have a complementary metal-oxide-semiconductor (CMOS) structure provided between the first power line M1_R1 and the second power line M1_R2.

Each of the first and second active regions AR1 and AR2 may have a first width WI in a first direction D1. The first direction D1 may be a direction parallel to a surface of the substrate 100. A first height HE1 may indicate a length in the first direction D1 of the single height cell SHC. The first height HE1 may be substantially the same as a distance (e.g., pitch) between the first power line M1_R1 and the second power line M1_R2.

The single height cell SHC may constitute one logic cell. In this description, the logic cell may be a logic device (e.g., AND, OR, XOR, XNOR, and/or inverter) that performs a specific function. For example, the logic cell may include transistors for constituting a logic device, and may also include wiring lines that connect the transistors to each other.

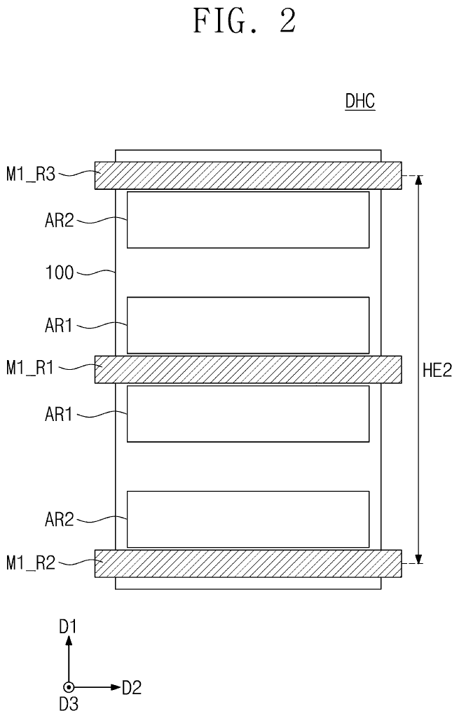

Referring to FIG. 2, a double height cell DHC may be provided. For example, a substrate 100 may be provided thereon with a first power line M1_R1, a second power line M1_R2, and a third power line M1_R3. The first power line M1_R1 may be disposed between the second power line M1_R2 and the third power line M1_R3. The third power line M1_R3 may be a conduction path for providing a source voltage VSS.

The double height cell DHC may be between the second power line M1_R2 and the third power line M1_R3. The double height cell DHC may include two first active regions AR1 and two second active regions AR2.

One of the two second active regions AR2 may be adjacent to the second power line M1_R2. The other of the two second active regions AR2 may be adjacent to the third power line M1_R3. The two first active regions AR1 may be adjacent to the first power line M1_R1. When viewed in a plan view, the first power line M1_R1 may be disposed between the two first active regions AR1.

A length in the first direction D1 of the double height cell DHC may be defined as a second height HE2. The second height HE2 may be about twice the first height HE1 of FIG. 1. The two first active regions AR1 of the double height cell DHC may be integrally connected to each other to serve as one active region.

In the inventive concept, the double height cell DHC shown in FIG. 2 may be defined as a multi-height cell. The multi-height cell may include a triple height cell whose cell height is about three times that of the single height cell SHC.

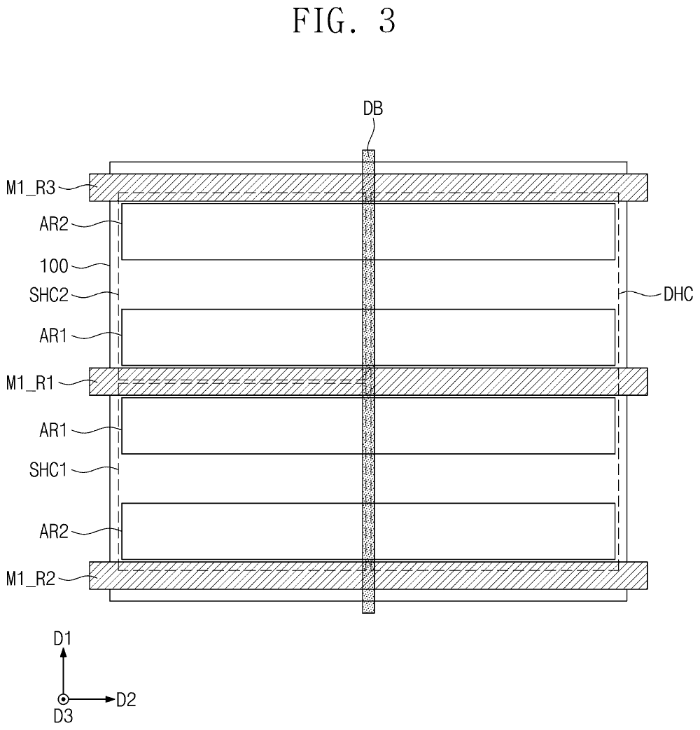

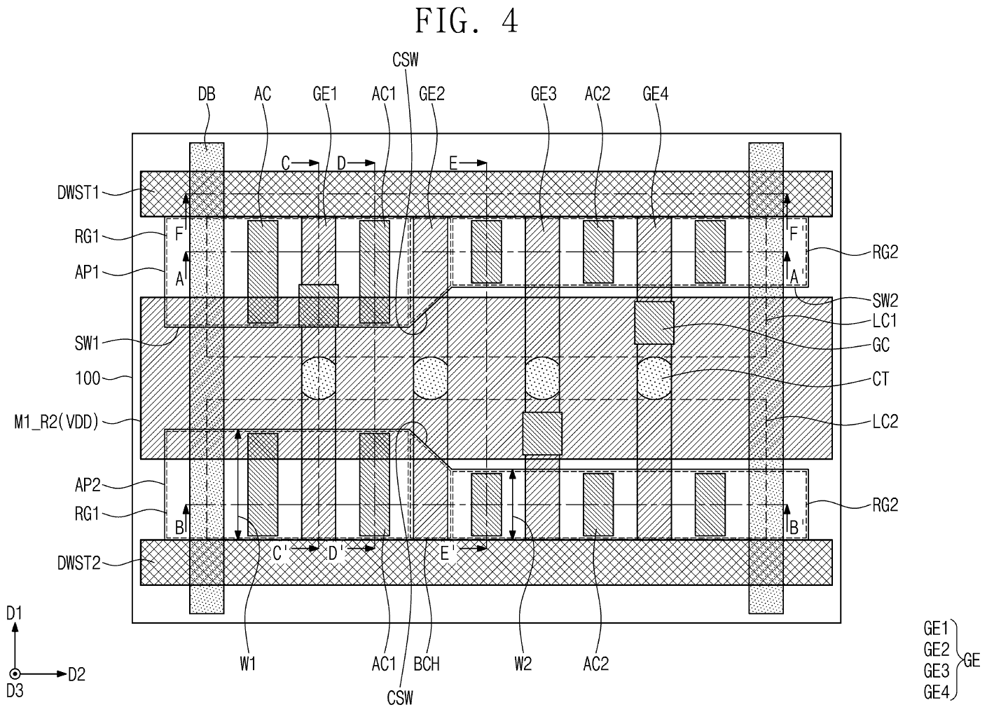

Referring to FIG. 3, a substrate 100 may be provided thereon with a first single height cell SHC1, a second single height cell SHC2, and a double height cell DHC that are two-dimensionally disposed. The first single height cell SHC1 may be disposed between a first power line M1_R1 and a second power line M1_R2. The second single height cell SHC2 may be disposed between the first power line M1_R1 and a third power line M1_R3. The second single height cell SHC2 may be adjacent in a first direction D1 to the first single height cell SHC1.

The double height cell DHC may be disposed between the second power line M1_R2 and the third power line M1_R3. The double height cell DHC may be adjacent in a second direction D2 to the first and second single height cells SHC1 and SHC2. The second direction D2 may be a direction parallel to the surface of the substrate 100 and intersecting the first direction D1.

A separation structure DB may be provided between the first single height cell SHC1 and the double height cell DHC and between the second single height cell SHC2 and the double height cell DHC. The separation structure DB may electrically separate an active region of the double height cell DHC from an active region of each of the first and second single height cells SHC1 and SHC2 in the second direction D2 and extend longitudinally in the first direction D1.

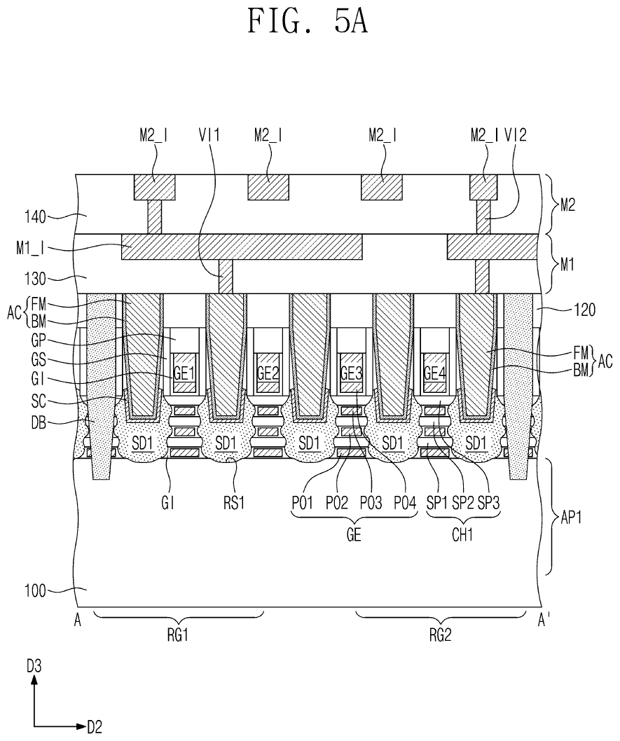

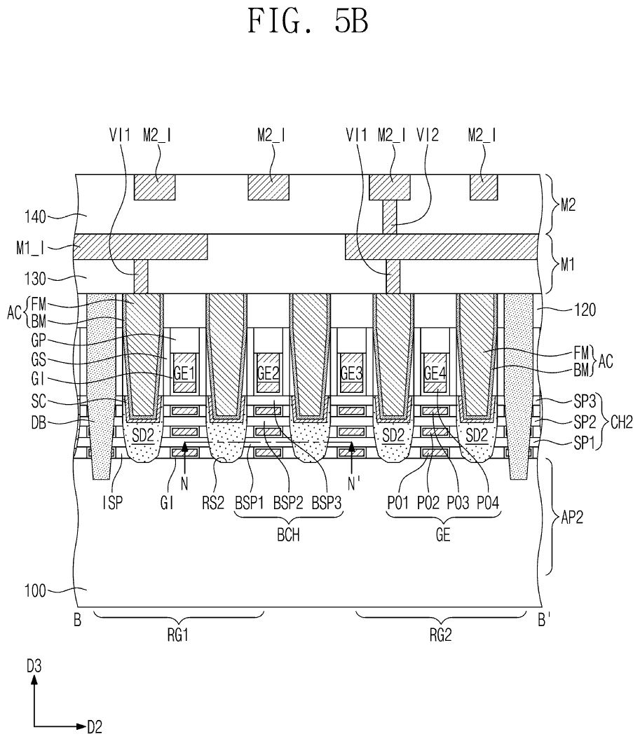

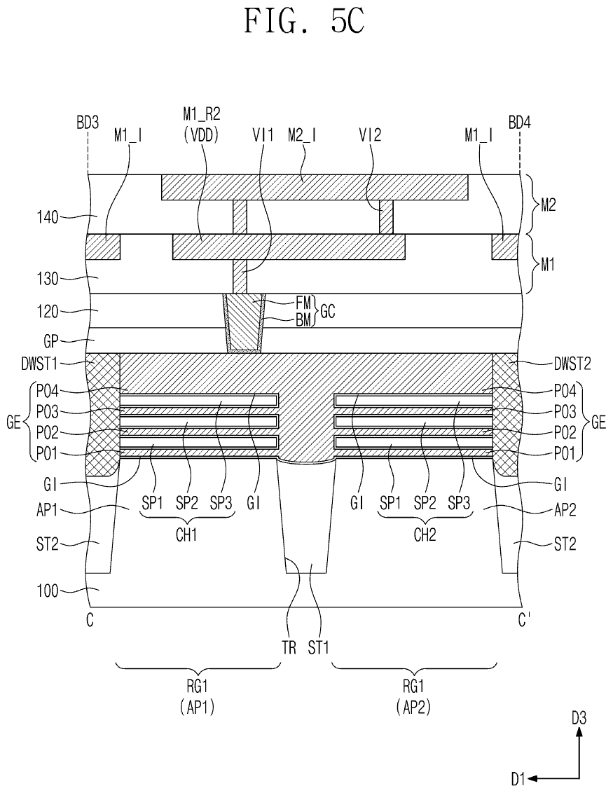

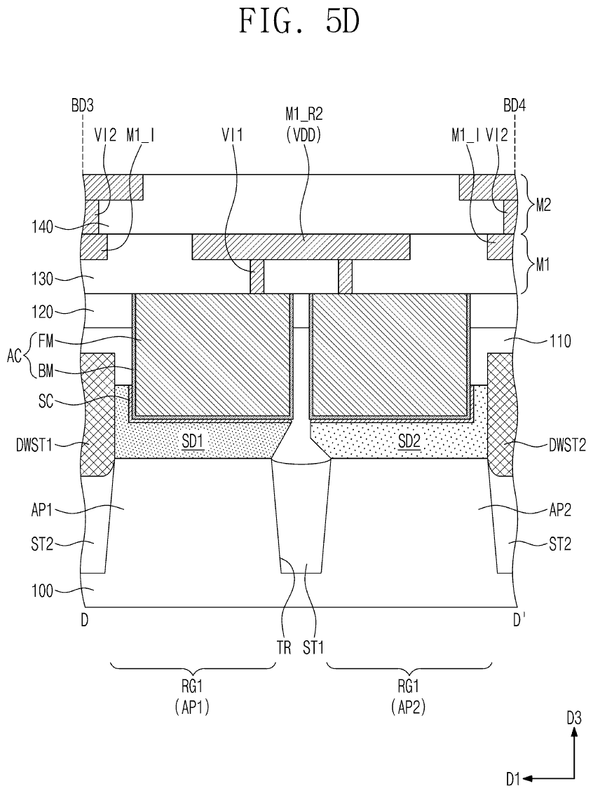

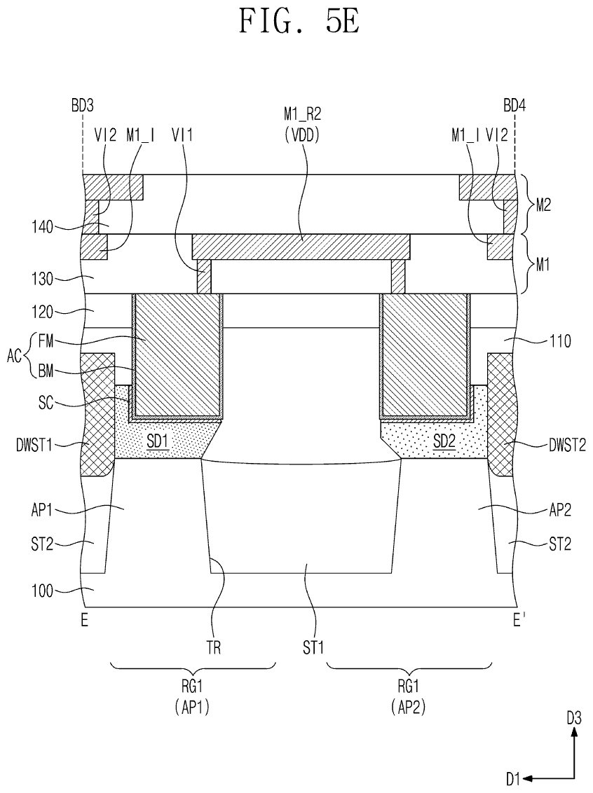

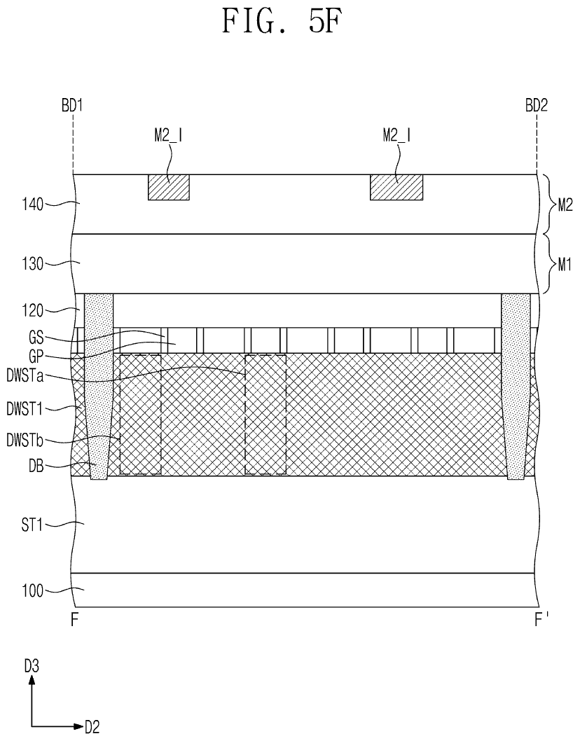

FIG. 4 is a schematic plan view illustrating a semiconductor device according to embodiments of the inventive concept. FIGS. 5A to 5F are schematic cross-sectional views taken along lines A-A′, B-B′, C-C′, D-D′, E-E′, and F-F′ of FIG. 4, respectively. A semiconductor device shown in FIGS. 4 and 5A to 5D is an example of the single height cell SHC illustrated in FIG. 1.

Referring to FIGS. 4 and 5A to 5F, a single height cell SHC may be provided on a substrate 100. Logic transistors constituting a logic circuit may be disposed on the single height cell SHC. The substrate 100 may be a semiconductor substrate including silicon, germanium, or silicon-germanium, or a compound semiconductor substrate. As an example, the substrate 100 may be a silicon substrate. As another example, the substrate 100 may include a silicon-based insulating layer. That is, the substrate 100 may be an insulating substrate. The above insulating substrate may include, for example, a silicon oxide layer, a silicon nitride layer, or a silicon oxynitride layer.

Referring again to FIG. 1, the substrate 100 may include a first active region AR1 and a second active region AR2. Each of the first and second active regions AR1 and AR2 may extend in a second direction D2. In one embodiment, the first active region AR1 may be a PMOSFET region, and the second active region AR2 may be an NMOSFET region.

Referring again to FIGS. 4 and 5A to 5F, a first active pattern AP1 and a second active pattern AP2 may be defined by a trench TR formed on an upper portion of the substrate 100. The first active pattern AP1 may be provided on the first active region AR1, and the second active pattern AP2 may be provided on the second active region AR2 (see FIG. 1). The first and second active patterns AP1 and AP2 may extend in the second direction D2. The first and second active patterns AP1 and AP2 may be respective portions of the substrate 100 that extend in a third direction D3 (i.e., the vertical direction) perpendicular to the surface of the substrate 100.

Device isolation layers ST1 and ST2 may be provided on the substrate 100. The first and second active patterns AP1 and AP2 may be defined by the device isolation layers ST1 and ST2. The device isolation layers ST1 and ST2 may fill the trench TR. The term “fill” (or “fills,” or like terms) is intended to refer to either completely filling a defined space (e.g., the trench TR) or partially filling the defined space; that is, the defined space need not be entirely filled but may, for example, be partially filled or have voids or other spaces throughout. In detail, the first device isolation layer ST1 may fill the trench TR between the first and second active patterns AP1 and AP2 adjacent in the first direction D1. The second device isolation layer ST2 may fill the trench TR between the first active patterns AP1 or the trench TR between the second active patterns AP2 adjacent in the first direction D1. The device isolation layers ST1 and ST2 may include a silicon oxide layer. The device isolation layers ST1 and ST2 may not cover first and second channel patterns CH1 and CH2 to be described later. The term “cover” (or “covers,” or like terms), as may be used herein, is intended to broadly refer to an element, structure or layer that is on or over another element, structure or layer, either directly or with one or more other intervening elements, structures or layers therebetween.

A first channel pattern CH1 may be provided on the first active pattern AP1. A second channel pattern CH2 may be provided on the second active pattern AP2. Each of the first channel pattern CH1 and the second channel pattern CH2 may include a first semiconductor pattern SP1, a second semiconductor pattern SP2, and a third semiconductor pattern SP3 that are sequentially stacked in the third direction D3. The first to third semiconductor patterns SP1, SP2, and SP3 may be spaced apart from each other in a vertical direction (i.e., the third direction D3).

Each of the first to third semiconductor patterns SP1, SP2, and SP3 may include silicon (Si), germanium (Ge), or silicon-germanium (SiGe). For example, each of the first to third semiconductor patterns SP1, SP2, and SP3 may include crystalline silicon. In one embodiment of the inventive concept, the first to third semiconductor patterns SP1, SP2, and SP3 may be stacked nanosheets. In one embodiment of the inventive concept, the first to third semiconductor patterns SP1, SP2, and SP3 adjacent to backbone structures DWST1 and DWST2 described later may be stacked forksheets.

A plurality of first source/drain patterns SD1 may be provided on the first active pattern AP1. A plurality of first recesses RS1 may be formed on an upper portion of the first active pattern AP1. The first source/drain patterns SD1 may be provided in each of the first recesses RS1. The first source/drain patterns SD1 may be impurity regions of a first conductivity type (e.g., p-type). The first channel pattern CH1 may be interposed between an adjacent pair of the first source/drain patterns SD1. That is, the stacked first to third semiconductor patterns SP1, SP2, and SP3 may connect a pair of first source/drain patterns SD1 to each other. The term “connect” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items.

A plurality of second source/drain patterns SD2 may be provided on the second active pattern AP2. A plurality of second recesses RS2 may be formed on an upper portion of the second active pattern AP2. The second source/drain patterns SD2 may be provided in each of the second recesses RS2. The second source/drain patterns SD2 may be impurity regions of a second conductivity type (e.g., n-type). The second channel pattern CH2 may be interposed between an adjacent pair of the second source/drain patterns SD2. That is, the stacked first to third semiconductor patterns SP1, SP2, and SP3 may connect a pair of second source/drain patterns SD2 to each other.

The first and second source/drain patterns SD1 and SD2 may be epitaxial patterns formed by a selective epitaxial growth (SEG) process. For example, an upper surface of each of the first and second source/drain patterns SD1 and SD2 may be higher than an upper surface of the third semiconductor pattern SP3, relative to the surface of the substrate as a reference layer. As another example, the upper surface of at least one of the first and second source/drain patterns SD1 and SD2 may be at substantially the same level as the upper surface of the third semiconductor pattern SP3; that is, the upper surface of at least one of the first and second source/drain patterns SD1, SD2 may be coplanar with the upper surface of the third semiconductor pattern SP3.

In one embodiment of the inventive concept, the first source/drain patterns SD1 may include a semiconductor device (e.g., SiGe) having a lattice constant greater than a lattice constant of a semiconductor device (e.g., Si) of the substrate 100. Accordingly, the pair of first source/drain patterns SD1 may provide a compressive stress to the first channel pattern CH1 therebetween. The second source/drain patterns SD2 may include the same semiconductor device (e.g., Si) as the substrate 100.

Each of the first source/drain patterns SD1 may include a buffer layer and a main layer on the buffer layer. A volume of the main layer may be larger than a volume of the buffer layer. Each of the buffer layer and the main layer may include silicon-germanium (SiGe), although embodiments are not limited thereto. In detail, the buffer layer may contain a relatively low concentration of germanium (Ge). In another embodiment of the inventive concept, the buffer layer may contain only silicon (Si) excluding germanium (Ge). A concentration of germanium (Ge) in the buffer layer may be 0 atomic percent (at %) to 30 at %.

The main layer may contain a relatively high concentration of germanium (Ge). For example, a concentration of germanium (Ge) in the main layer may be 30 at % to 70 at %. A concentration of germanium (Ge) in the main layer may increase in the third direction D3. For example, the main layer adjacent to the buffer layer may have a concentration of germanium (Ge) of about 40 at %, but the upper portion of the main layer may have a concentration of germanium (Ge) of about 60 at %.

Each of the buffer layer and the main layer may include one more impurities (e.g., boron, gallium, or indium) that cause the first source/drain pattern SD1 to have a p-type conductivity. An impurity concentration of each of the buffer layer and the main layer may be 1E¹⁸ atom/cm³ to 5E²² atom/cm³. An impurity concentration of the main layer may be greater than an impurity concentration of the buffer layer.

The buffer layer may protect the main layer during a process of replacing sacrificial layers SAL described below with first to third inner electrodes PO1, PO2, and PO3 of a gate electrode GE. That is, the buffer layer may prevent an etchant that removes the sacrificial layers SAL from penetrating into the main layer and etching the main layer.

Each of the second source/drain patterns SD2 may include silicon (Si). The second source/drain pattern SD2 may further include one or more impurities (e.g., phosphorus, arsenic, or antimony) that cause the second source/drain pattern SD2 to have an n-type conductivity. An impurity concentration of the second source/drain pattern SD2 may be 1E¹⁸ atom/cm³ to 5E²² atom/cm³.

In one embodiment of the inventive concept, a sidewall of the first source/drain pattern SD1 may have an uneven embossing shape. That is, the sidewall of the first source/drain pattern SD1 may have a wave-shaped profile. The sidewall of the first source/drain pattern SD1 may protrude toward first to third inner electrodes PO1, PO2, and PO3 of a gate electrode GE to be described later.

Gate electrodes GE may be provided on the first and second channel patterns CH1 and CH2. Each of the gate electrodes GE may extend in the first direction D1 across the first and second channel patterns CH1 and CH2. Each of the gate electrodes GE may vertically overlap the first and second channel patterns CH1 and CH2. As used herein, “an element A overlapping an element B in a direction X” (or similar language) means that there is at least one line that extends in the direction X and intersects both the elements A and B. The gate electrodes GE may be disposed in the second direction D2 with a first pitch.

The gate electrode GE may include a first inner electrode PO1 interposed between each of the first and second active patterns AP1 and AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring to FIG. 5C, the gate electrode GE may be provided on an upper surface, a lower surface, and a side surface of each of the first to third semiconductor patterns SP1, SP2, and SP3. That is, a transistor according to the present embodiment may be a three-dimensional field effect transistor (e.g., multi-bridge-channel field-effect transistor (MBCFET) or gate-all-around field-effect transistor (GAAFET)) in which the gate electrode GE three-dimensionally surrounds a channel. The term “surrounds” (or “surrounding,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. In detail, the transistor according to the present embodiment may be a three-dimensional field effect transistor in which the gate electrode GE extends from an upper surface of each of the first to third semiconductor patterns SP1, SP2, and SP3 to a lower surface thereof along one side surface thereof to surrounds three surfaces.

On the second active pattern AP2, inner spacers ISP may be interposed between the first to third inner electrodes PO1, PO2, and PO3 of the gate electrode GE and the second source/drain pattern SD2. Each of the first to third inner electrodes PO1, PO2, and PO3 of the gate electrode GE may be spaced apart from the second source/drain pattern SD2 with the inner spacer ISP interposed therebetween. The inner spacer ISP may prevent leakage current from the gate electrode GE.

Referring again to FIGS. 4 and 5A to 5F, a pair of gate spacers GS may be respectively disposed on both sidewalls of the outer electrode PO4 of the gate electrode GE. The gate spacers GS may extend in the first direction D1 along the gate electrode GE. Upper surfaces of the gate spacers GS may be coplanar with an upper surface of the gate capping pattern GP. In one embodiment, the gate spacers GS may include at least one of SiCN, SiCON, and SiN. In another embodiment, the gate spacers GS may include a multi-layer formed of at least two of SiCN, SiCON, and SiN.

A gate capping pattern GP may be provided on the gate electrode GE. The gate capping pattern GP may extend in the first direction D1 along the gate electrode GE. The gate capping pattern GP may include a material having etch selectivity with respect to first and second interlayer insulating layers 110 and 120 described below. In detail, the gate capping pattern GP may include at least one of SION, SiCN, SiCON, and SiN.

A gate insulating layer GI may be interposed between the gate electrode GE and the first channel pattern CH1 and between the gate electrode GE and the second channel pattern CH2. The gate insulating layer GI may cover an upper surface, a lower surface, and both side surfaces of each of the first to third semiconductor patterns SP1, SP2, and SP3. The gate insulating layer GI may cover an upper surface of the first device isolation layer ST1 under the gate electrode GE.

In one embodiment of the inventive concept, the gate insulating layer GI may include a silicon oxide layer, a silicon oxynitride layer, and/or a high dielectric constant (high-k) layer. For example, the gate insulating layer GI may have a structure in which a silicon oxide layer and a high-k layer are stacked. The high-k dielectric layer may include a high-k dielectric material having a higher dielectric constant than a silicon oxide layer. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In another embodiment, the semiconductor device of the inventive concept may include a negative capacitance (NC) FET using a negative capacitor. For example, the gate insulating layer GI may include a ferroelectric material layer having ferroelectric characteristics and a paraelectric material layer having paraelectric characteristics.

The gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work function metal that controls a threshold voltage of the transistor. As a thickness and a composition of the first metal pattern are adjusted, a desired threshold voltage of the transistor may be achieved. For example, the first to third inner electrodes PO1, PO2, and PO3 of the gate electrode GE may be formed of the first metal pattern, which is a work function metal.

The first metal pattern may include a metal nitride layer. For example, the first metal pattern may include at least one metal selected from the group consisting of titanium (Ti), tantalum (Ta), aluminum (Al), tungsten (W), molybdenum (Mo), and nitrogen (N). Furthermore, the first metal pattern may further include carbon (C). The first metal pattern may include a plurality of stacked work function metal layers.

The second metal pattern may include a metal having lower resistance than the first metal pattern. For example, the second metal pattern may include at least one metal selected from the group consisting of tungsten (W), aluminum (Al), titanium (Ti), and tantalum (Ta). For example, the outer electrode PO4 of the gate electrode GE may include the first metal pattern and the second metal pattern on the first metal pattern.

Backbone structures DWST1 and DWST2 may be provided on the second device isolation layer ST2. That is, the backbone structures DWST1 and DWST2 may vertically overlap the second device isolation layer ST2. The backbone structures DWST1 and DWST2 may be provided on each of a side surface of the first active region AR1 and a side surface of the second active region AR2 on the substrate 100. The backbone structures DWST1 and DWST2 may not be provided between the first active pattern AP1 and the second active pattern AP2. The backbone structures DWST1 and DWST2 may extend in the second direction D2. When viewed in a plan view, the backbone structures DWST1 and DWST2 may have a bar shape extending in the second direction D2.

The backbone structures DWST1 and DWST2 may include a first backbone structure DWST1 and a second backbone structure DWST2. The first backbone structure DWST1 may be provided on a side surface of the first active pattern AP1. The second backbone structure DWST2 may be provided on a side surface of the second active pattern AP2. The first backbone structure DWST1 and the second backbone structure DWST2 may be spaced apart from each other in the first direction D1.

Referring to FIG. 5F, the first backbone structure DWST1 may include a first backbone portion DWSTa and a second backbone portion DWSTb. Each of the first and second backbone portions DWSTa and DWSTb may be defined as a portion of the first backbone structure DWST1. The first backbone portion DWSTa may be in contact with the first source/drain pattern SD1. The second backbone portion DWSTb may be in contact with the gate electrode GE.

The first backbone structure DWST1 and the second backbone structure DWST2 may include an insulating material. For example, the insulating material may include silicon oxide, silicon nitride, silicon oxynitride, or a combination thereof.

A first interlayer insulating layer 110 may be provided on the substrate 100. The first interlayer insulating layer 110 may cover the gate spacers GS, the first and second source/drain patterns SD1 and SD2, and the second backbone structure DWST2. An upper surface of the first interlayer insulating layer 110 may be substantially coplanar with an upper surface of the gate capping pattern GP and an upper surface of the gate spacer GS. A second interlayer insulating layer 120 may be disposed on the first interlayer insulating layer 110 to cover the gate capping pattern GP. A third interlayer insulating layer 130 may be provided on the second interlayer insulating layer 120. A fourth interlayer insulating layer 140 may be provided on the third interlayer insulating layer 130. For example, the first to fourth interlayer insulating layers 110 to 140 may include a silicon oxide layer.

A pair of separation structures DB facing each other in the second direction D2 may be provided on both sides of the single height cell SHC. For example, the pair of separation structures DB may be provided on boundaries of the single height cell SHC, respectively. The separation structure DB may extend parallel to the gate electrodes GE1 and GE2 in the first direction D1. A pitch between the separation structure DB and the gate electrodes GE1 and GE2 adjacent thereto may be the same as the first pitch.

The separation structure DB may extend in the third direction D3 through the first interlayer insulating layer 110 at least partially into the first and second active patterns AP1 and AP2. The separation structure DB may penetrate (i.e., extend in) an upper portion of each of the first and second active patterns AP1 and AP2. The separation structure DB may electrically separate the active region of the single height cell SHC from an active region of an adjacent cell.

Active contacts AC may be provided that penetrate the first and second interlayer insulating layers 110 and 120 and are electrically connected to the first and second source/drain patterns SD1 and SD2, respectively. A pair of active contacts AC may be provided on each of two side surfaces of the gate electrode GE1 or GE2. When viewed in a plan view, the active contact AC may have a bar shape extending in the first direction D1.

The active contact AC may be a self-aligned contact. That is, the active contact AC may be formed in a self-aligned manner using the gate capping pattern GP and the gate spacer GS. For example, the active contact AC may cover at least a portion of a sidewall of the gate spacer GS. Although not shown, the active contact AC may cover a portion of an upper surface of the gate capping pattern GP.

A metal-semiconductor compound layer SC, for example, a silicide layer, may be interposed between the active contact AC and the first source/drain pattern SD1 and between the active contact AC and the second source/drain pattern SD2, respectively. The active contact AC may be electrically connected to the source/drain patterns SD1 and SD2 through the metal-semiconductor compound layer SC. For example, the metal-semiconductor compound layer SC may include at least one of titanium-silicide, tantalum-silicide, tungsten-silicide, nickel-silicide, or cobalt-silicide.

Gate contacts GC may be provided that are electrically connected to the gate electrodes GE by penetrating the second interlayer insulating layer 120 and the gate capping pattern GP. When viewed in a plan view, the gate contacts GC may overlap the first active region AR1 and the second active region AR2, respectively. For example, the gate contact GC may be provided on the first active pattern AP1.

In one embodiment of the inventive concept, an upper portion of the active contact AC adjacent to the gate contact GC may be filled with an upper insulating pattern. A bottom surface of the upper insulating pattern may be lower than a bottom surface of the gate contact GC. That is, the upper surface of the active contact AC adjacent to the gate contact GC may be lower than the bottom surface of the gate contact GC by the upper insulating pattern, relative to the surface of the substrate 100. Accordingly, the upper insulating pattern may prevent the gate contact GC from coming into contact with the adjacent active contact AC, thereby preventing a short circuit.

Each of the active contact AC and the gate contact GC may include a conductive pattern FM and a barrier pattern BM surrounding the conductive pattern FM. For example, the conductive pattern FM may include at least one metal among aluminum, copper, tungsten, molybdenum, and cobalt. The barrier pattern BM may cover sidewalls and a bottom surface of the conductive pattern FM. The barrier pattern BM may include a metal layer/metal nitride layer. The metal layer may include at least one of titanium, tantalum, tungsten, nickel, cobalt, or platinum. The metal nitride layer may include at least one of a titanium nitride layer (TiN), a tantalum nitride layer (TaN), a tungsten nitride layer (WN), a nickel nitride layer (NiN), a cobalt nitride layer (CON), or a platinum nitride layer (PIN).

A first metal layer M1 may be provided in the third interlayer insulating layer 130. For example, the first metal layer M1 may include a first power line M1_R1, a second power line M1_R2, and first wiring lines M1_I. Each of the lines M1_R1, M1_R2, and M1_I of the first metal layer M1 may extend parallel to each other in the second direction D2.

In detail, the first and second power lines M1_R1 and M1_R2 may be provided on boundaries of the single height cell SHC, respectively. The first power line M1_R1 and the second power line M1_R2 may extend in the second direction D2.

The first wiring lines M1_I of the first metal layer M1 may be disposed between the first and second power lines M1_R1 and M1_R2. The first wiring lines M1_I of the first metal layer M1 may be disposed in the first direction D1 with a second pitch. The second pitch may be smaller than the first pitch. A line width of each of the first wiring lines M1_I may be smaller than a line width of each of the first and second power lines M1_R1 and M1_R2.

The first metal layer M1 may further include first vias VI1. The first vias VI1 may be provided below the lines M1_R1, M1_R2, and M1_I of the first metal layer M1, respectively. The active contact AC and the lines of the first metal layer M1 may be electrically connected to each other through the first vias VI1. The gate contact GC and the lines of the first metal layer M1 may be electrically connected to each other through the first vias VI1.

The lines of the first metal layer M1 and the first vias VI1 thereunder may be formed by separate processes. That is, the line of the first metal layer M1 and the first via VI1 may each be formed by a single damascene process. The semiconductor device according to the present embodiment may be formed by using a process of less than 20 nm.

A second metal layer M2 may be provided in the fourth interlayer insulating layer 140. The second metal layer M2 may include a plurality of second wiring lines M2_I. Each of the second wiring lines M2_I of the second metal layer M2 may have a line shape or a bar shape extending in the first direction D1. That is, the second wiring lines M2_I may extend parallel to each other in the first direction D1.

The second metal layer M2 may further include second vias VI2 provided below each of the second wiring lines M2_I. The line of the first metal layer M1 and the wiring line of the second metal layer M2 may be electrically connected to each other through the second vias VI2. For example, the wiring line of the second metal layer M2 and the second vias VI2 thereunder may be formed together by a dual damascene process.

The line of the first metal layer M1 and the wiring line of the second metal layer M2 may include the same or different conductive materials. For example, the line of the first metal layer M1 and the wiring line of the second metal layer M2 may include at least one metal material selected from aluminum, copper, tungsten, molybdenum, ruthenium, and cobalt. Although not shown, metal layers (e.g., M3, M4, M5 . . . ) staked on the fourth interlayer insulating layer may be additionally disposed. Each of the stacked metal layers may include lines for routing between cells.

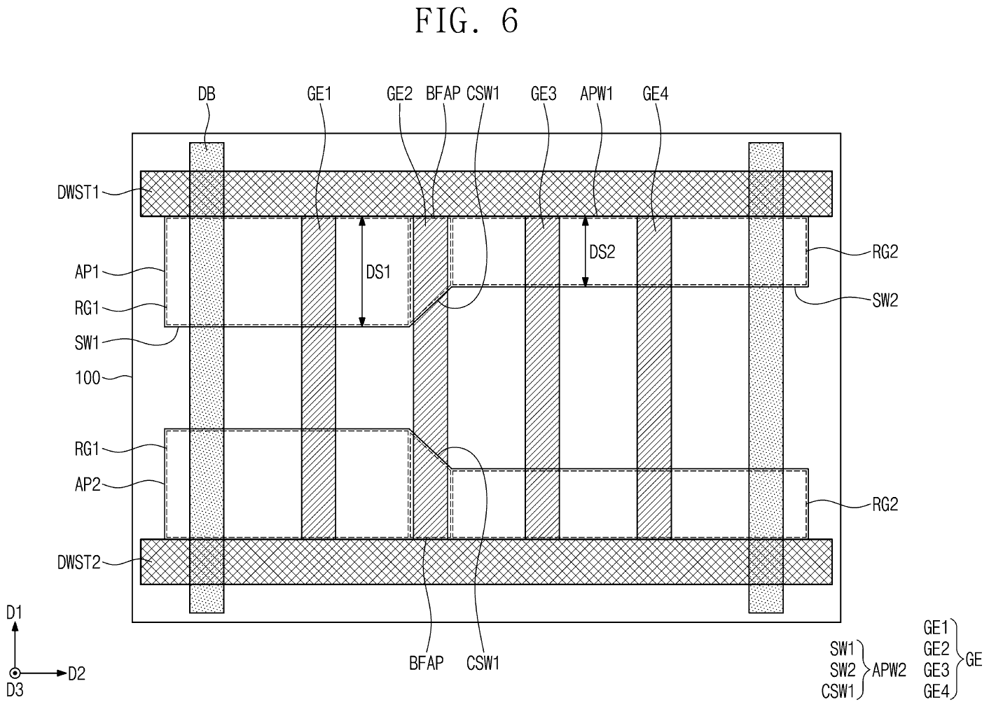

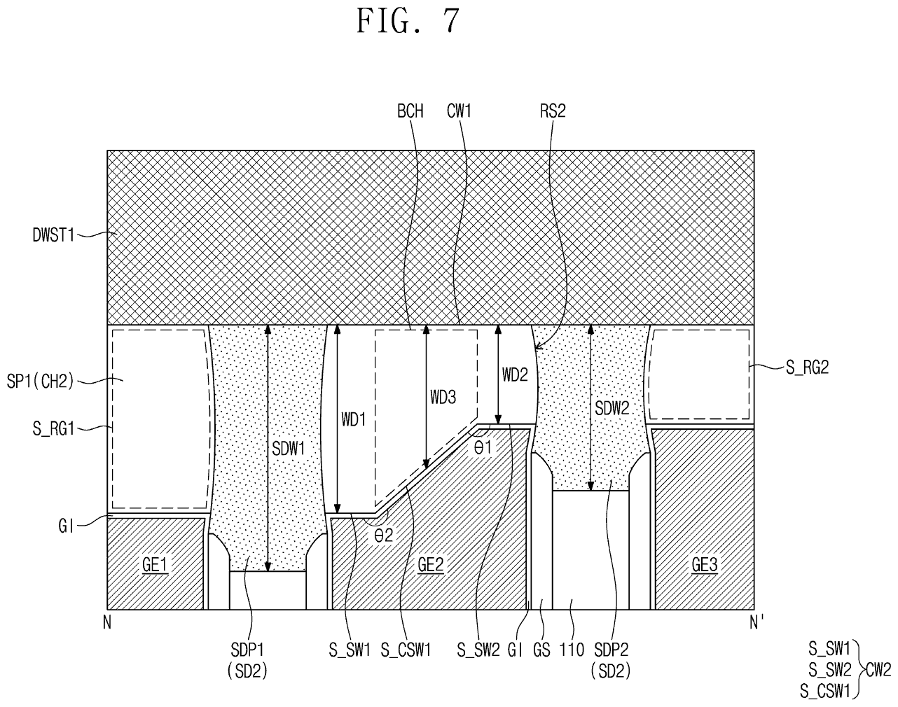

FIG. 6 is a schematic plan view for illustrating a semiconductor device according to an embodiment of the inventive concept. FIG. 7 is a schematic cross-sectional view taken along line N-N′ of FIG. 5B according to an embodiment of the inventive concept. The active patterns AP1 and AP2 and the backbone structures DWST1 and DWST2 will be described in more detail with reference to FIGS. 6 and 7.

Referring to FIG. 6, the first active pattern AP1 may include a first region RG1 and a second region RG2 spaced apart in a second direction D2. A buffer active pattern BFAP may be disposed between the first region RG1 and the second region RG2.

The first active pattern AP1 may include a first active sidewall APW1 that is directly in contact with the first backbone structure DWST1. The first active pattern AP1 may include a second active sidewall APW2 spaced apart from the first active sidewall APW1 in the first direction D1. The second active sidewall APW2 may not be in contact with the first backbone structure DWST1. The second active sidewall APW2 may be spaced apart from the first backbone structure DWST1 in the first direction D1.

The second active sidewall APW2 may include a first sidewall SW1 and a second sidewall SW2 extending in the second direction D2. The first sidewall SW1 may be one sidewall of the first region RG1. The second sidewall SW2 may be one sidewall of the second region RG2. The second active sidewall APW2 may include a first buffer active sidewall CSW1 connecting the first sidewall SW1 and the second sidewall SW2. The first buffer active sidewall CSW1 may be one sidewall of the buffer active pattern BFAP. In one or more embodiments, an angle formed by the first buffer active sidewall CSW1 and the first sidewall SW1 may be between about 91° and 179°. An angle between the first buffer active sidewall CSW1 and the second sidewall SW2 may be about 181° to 269°.

The first region RG1 may include a first distance DS1 between the first backbone structure DWST1 and the first sidewall SW1. The first distance DS1 may be a distance in the first direction D1 between the first active sidewall APW1 and the first sidewall SW1. The first distance DS1 may be a width of the first region RG1 in the first direction D1. The second region RG2 may include a second distance DS2 between the first backbone structure DWST1 and the second sidewall SW2. The second distance DS2 may be a distance in the first direction D1 between the first active sidewall APW1 and the second sidewall SW2. The second distance DS2 may be a width in the first direction D1 of the second region RG2.

A distance in the first direction D1 between the first active sidewall APW1 and the second active sidewall APW2 may be variously changed from the first region RG1 toward the second region RG2. For example, the distance in the first direction D1 between the first active sidewall APW1 and the second active sidewall APW2 may decrease from the first region RG1 toward the second region RG2, such that the second distance DS2 is less than the first distance DS1. As another example (not explicitly shown), the distance in the first direction D1 between the first active sidewall APW1 and the second active sidewall APW2 may increase from the first region RG1 toward the second region RG2, such that the second distance DS2 is greater than the first distance DS1.

For example, the first buffer active sidewall CSW1 may be configured to transition from the first distance DS1 into the second distance DS2 as the second active sidewall APW2 extends in the second direction D2 between the first region RG1 and the second region RG2. The first buffer active sidewall CSW1 may form an acute angle with the second direction D2 and may extend from the first sidewall SW1 to the second sidewall SW2. A width of the first active pattern AP1 may be changed by the first buffer active sidewall CSW1. That is, the buffer active pattern BFAP may be a portion where the width of the first active pattern AP1 is changed.

The second active pattern AP2 may be substantially the same as the first active pattern AP1 described above. When viewed in a plan view, the second active pattern AP2 may be symmetrical with the first active pattern AP1.

Referring to FIG. 7, the second channel patterns CH2 may include a first channel region S_RG1 and a second channel region S_RG2 spaced apart in the second direction D2. The second channel patterns CH2 may include a buffer channel pattern BCH disposed between the first channel region S_RG1 and the second channel region S_RG2.

The second channel patterns CH2 may include a first channel sidewall CW1 and a second channel sidewall CW2 spaced apart from each other in the first direction D1. The first channel sidewall CW1 may be in direct contact with the first backbone structure DWST1. The second channel sidewall CW2 may not be in contact with the first backbone structure DWST1. The second channel sidewall CW2 may be spaced apart from the first backbone structure DWST1 in the first direction D1.

The second channel sidewall CW2 may include a first extension sidewall S_SW1 and a second extension sidewall S_SW2 extending in the second direction D2. The first extension sidewall S_SW1 may be one sidewall of the first channel region S_RG1. The second extension sidewall S_SW2 may be one sidewall of the second channel region S_RG2. The second channel sidewall CW2 may include a first connection sidewall S_CSW1 connecting the first extension sidewall S_SW1 and the second extension sidewall S_SW2. The first connection sidewall S_CSW1 may be one sidewall of the buffer channel pattern BCH. An angle θ1 formed by the first connection sidewall S_CSW1 and the first extension sidewall S_SW1 may be from 91° to 179°. An angle θ2 formed by the first connection sidewall S_CSW1 and the second extension sidewall S_SW2 may be from 181° to 269°.

A distance in the first direction D1 between the first channel sidewall CW1 and the second channel sidewall CW2 may be variously changed from the first channel region S_RG1 toward the second channel region S_RG2. For example, the distance in the first direction D1 between the first channel sidewall CW1 and the second channel sidewall CW2 may decrease from the first channel region S_RG1 toward the second channel region S_RG2. As another example, the distance in the first direction D1 between the first channel sidewall CW1 and the second channel sidewall CW2 may increase from the first channel region S_RG1 toward the second channel region S_RG2.

The first channel region S_RG1 may have a first width WD1 in the first direction D1. The second channel region S_RG2 may have a second width WD2 in the first direction D1. A width of the second channel patterns CH2 may be changed from the first channel region S_RG1 toward the second channel region S_RG2. The width of the second channel patterns CH2 may be changed from the first width WD1 to the second width WD2 in the second direction D2. The width of the second channel patterns CH2 may decrease or increase from the first channel region S_RG1 toward the second channel region S_RG2.

The buffer channel pattern BCH may have a third width WD3 in the first direction D1. The buffer channel pattern BCH may be configured such that the width of the second channel patterns CH2 is changed from the first width WD1 to the second width WD2. The third width WD3 may be smaller than the first width WD1 and larger than the second width WD2. In another example, the third width WD3 may be larger than the first width WD1 and smaller than the second width WD2.

The first width WD1 may be a distance in the first direction D1 between the first extended sidewall S_SW1 and the first backbone structure DWST1. The second width WD2 may be a distance in the first direction D1 between the second extended sidewall S_SW2 and the first backbone structure DWST1. The third width WD3 may be a distance in the first direction D1 between the first connection sidewall S_CSW1 and the first backbone structure DWST1. A distance between the first backbone structure DWST1 and the second channel sidewall CW2 may be variously changed from the first channel region S_RG1 toward the second channel region S_RG2.

For example, the first connection sidewall S_CSW1 may be configured to variously change the distance between the first backbone structure DWST1 and the second channel sidewall CW2. The first connection sidewall S_CSW1 may form an acute angle with respect to the second direction D2 and may extend from the first extension sidewall S_SW1 to the second extension sidewall S_SW2. The width of the second channel patterns CH2 may be variously changed by the first connection sidewall S_CSW1. That is, the buffer channel pattern BCH may be a portion where the width of the second channel patterns CH2 is changed.

The buffer channel pattern BCH may be disposed between a pair of second source/drain patterns SDP1 and SDP2 adjacent to each other in the second direction D2. The widths SDW1 and SDW2 of each of the pair of second source/drain patterns SDP1 and SDP2 may be different from each other. The first channel patterns CH1 may be substantially the same as the second channel patterns CH2 described above.

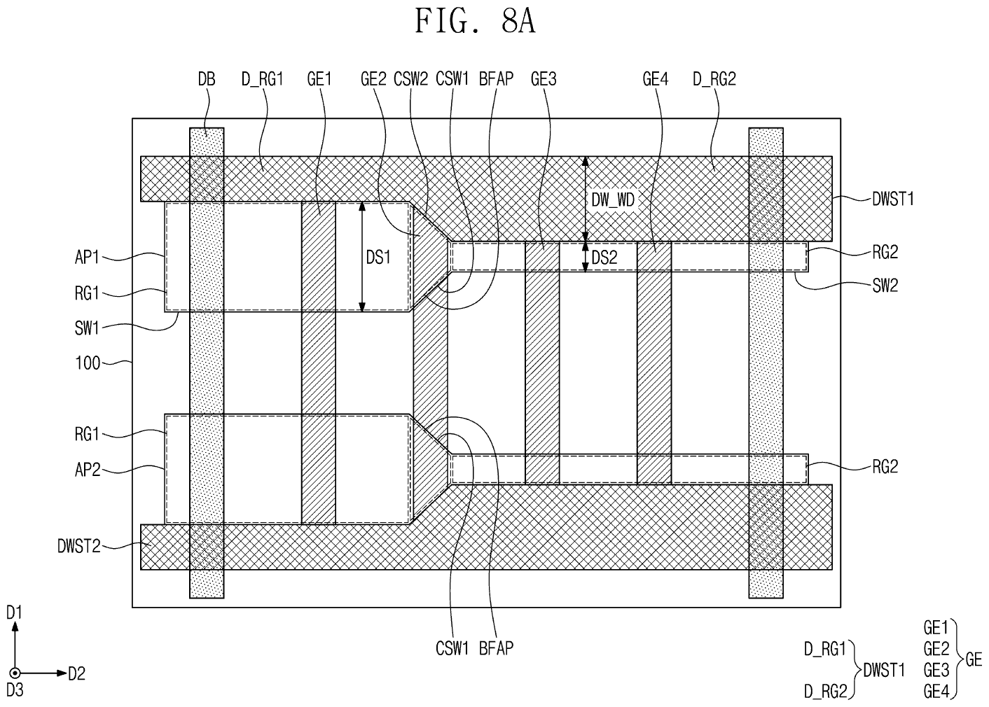

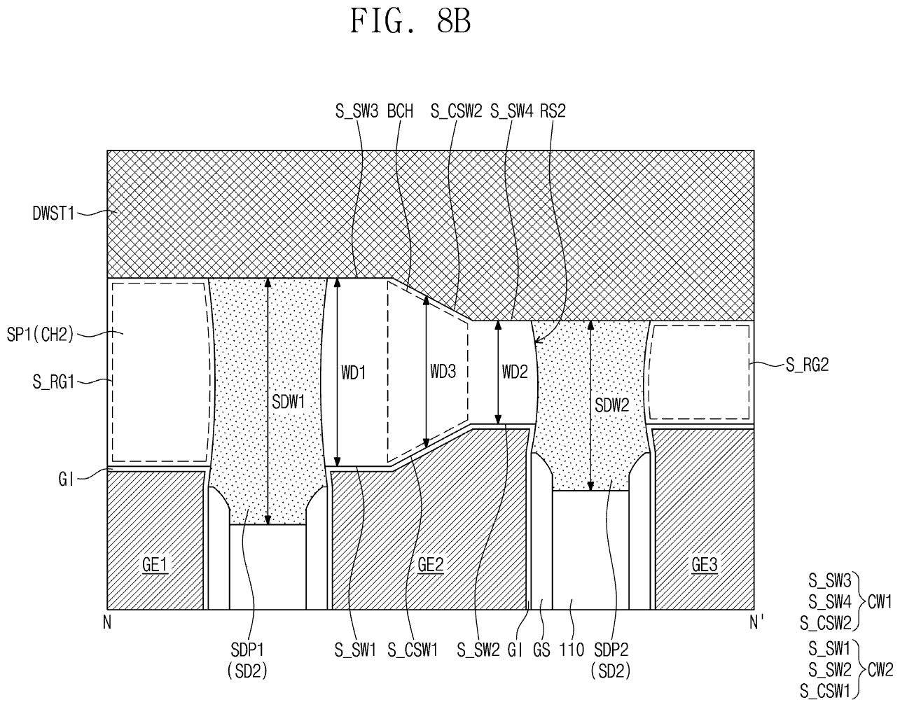

In the embodiments of the inventive concept described below, a detailed description of technical features overlapping with those described with reference to FIGS. 6 and 7 will be omitted, and differences will be described in detail. FIG. 8A is a schematic plan view for illustrating a semiconductor device according to another embodiment of the inventive concept. FIG. 8B is a schematic cross-sectional view along the N-N′ line of FIG. 5B, which is a drawing according to another embodiment of the inventive concept.

Referring to FIG. 8A, the first backbone structure DWST1 may include a first backbone region D_RG1 in contact with the first region RG1 and a second backbone region D_RG2 in contact with the second region RG2. A width DW_WD of the first backbone structure DWST1 in the first direction D1 may not be constant. For example, the width DW_WD of the first backbone structure DWST1 may be changed from the first backbone region D_RG1 toward the second backbone region D_RG2. The width DW_WD of the first backbone structure DWST1 may decrease or increase from the first backbone region D_RG1 toward the second backbone region D_RG2.

The buffer active pattern BFAP may include a first buffer active sidewall CSW1 and a second buffer active sidewall CSW2 that is direct contact with the first backbone structure DWST1. The second buffer active sidewall CSW2 may extend at an acute angle with respect to the second direction D2. The second buffer active sidewall CSW2 may extend obliquely with respect to the second direction D2. The second buffer active sidewall CSW2 may be configured to change the width of the first backbone structure DWST1 in the first direction D1. The second buffer active sidewall CSW2 may be configured to change the width of the first active pattern AP1.

When viewed in a plan view, the first buffer active sidewall CSW1 and the second buffer active sidewall CSW2 may have different inclinations. For example, the first buffer active sidewall CSW1 may have a positive slope, and the second buffer active sidewall CSW2 may have a negative slope. As another example, the first buffer active sidewall CSW1 may have a negative slope, and the second buffer active sidewall CSW2 may have a positive slope.

Referring to FIG. 8B, the first channel sidewall CW1 may include a third extension sidewall S_SW3 and a fourth extension sidewall S_SW4 extending in the second direction D2. The third extension sidewall S_SW3 may be one sidewall of the first channel region S_RG1. The fourth extension sidewall S_SW4 may be one sidewall of the second channel region S_RG2. The first channel sidewall CW1 may include a second connection sidewall S_CSW2 connecting the third extension sidewall S_SW3 and the fourth extension sidewall S_SW4. The second connection sidewall S_CSW2 may be one sidewall of the buffer channel pattern BCH. An angle formed between the second connection sidewall S_CSW2 and the third extension sidewall S_SW3 may be 91° to 179°. An angle formed between the second connection sidewall S_CSW2 and the fourth extension sidewall S_SW4 may be 181° to 269°.

The second connection sidewall S_CSW2 may extend at an acute angle with respect to the second direction D2. The second buffer active sidewall CSW2 (see FIG. 8A) may extend obliquely with respect to the second direction D2. The second buffer active sidewall CSW2 may be configured to change the width of the first backbone structure DWST1. The second buffer active sidewall CSW2 may be configured to change the width of the second channel patterns CH2.

Referring to FIGS. 8A and 8B, according to the inventive concept, the backbone structures DWST1 and DWST2 may be formed on one side of the active pattern AP1 and AP2, respectively, thereby reducing the area occupied by a unit cell constituting a logic element on the substrate. That is, the number of unit cells formed on the substrate may be increased, thereby improving integration of the semiconductor device.

According to the inventive concept, the width of the active pattern AP1 and AP2 and the width of the channel pattern CH1 and CH2 may be continuously changed. One sidewall of the active pattern AP1 and AP2 may be in direct contact with the backbone structure DWST1 and DWST2, and the other sidewall may be spaced apart from the backbone structure DWST1 and DWST2. In this case, the distance between the sidewalls of the active patterns AP1 and AP2 and the backbone structures DWST1 and DWST2 may be continuously changed. The sidewalls of the active patterns AP1 and AP2 may be formed in an obliquely extended shape, and thus the widths of the active patterns AP1 and AP2 may be implemented in various ways. As a result, electrical characteristics and reliability of the semiconductor device may be improved.

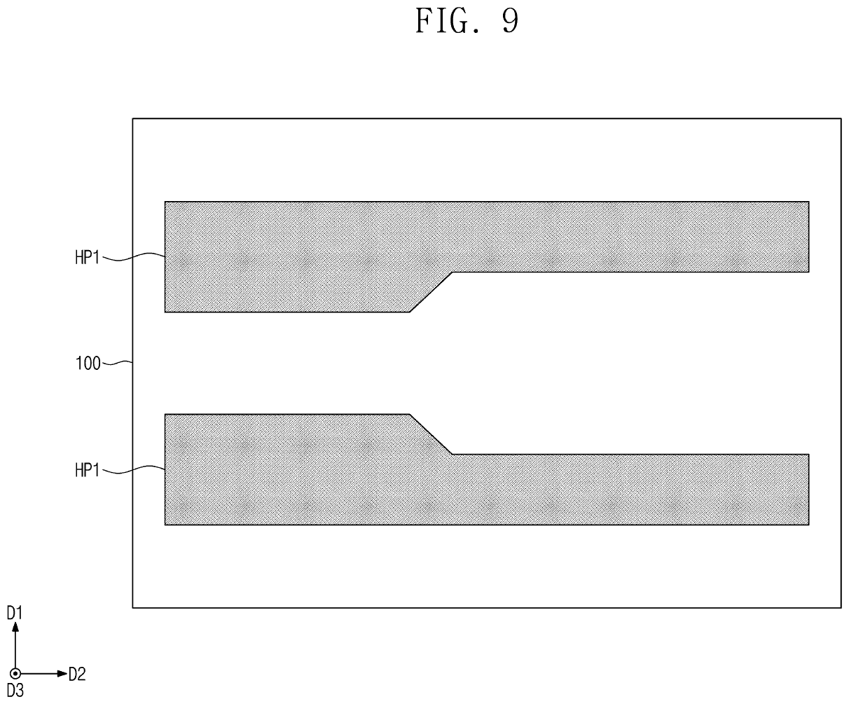

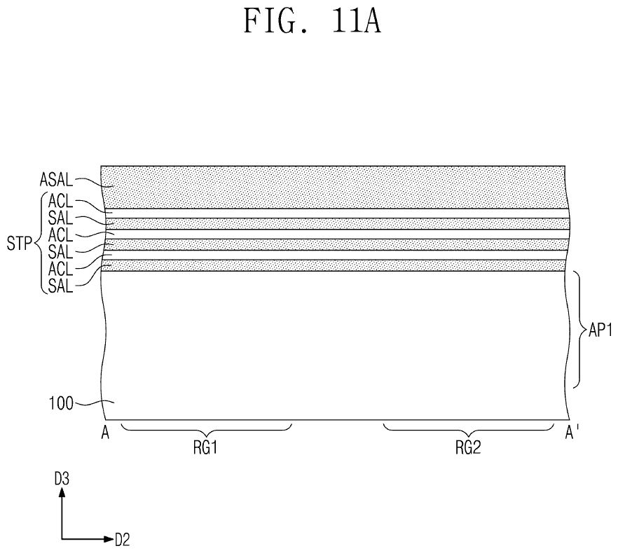

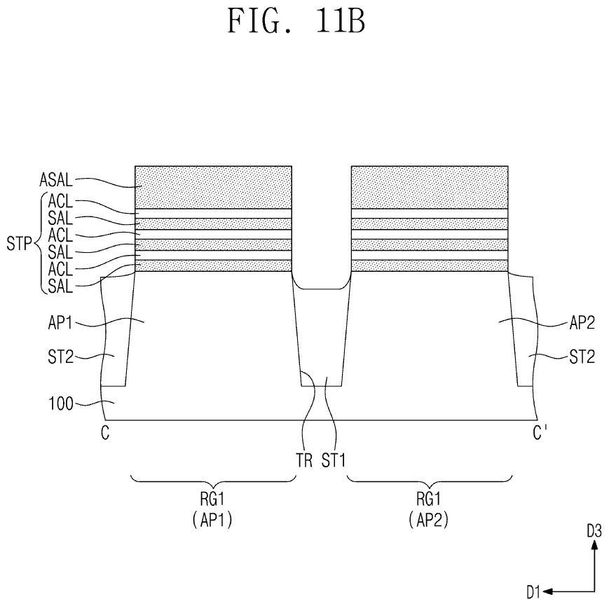

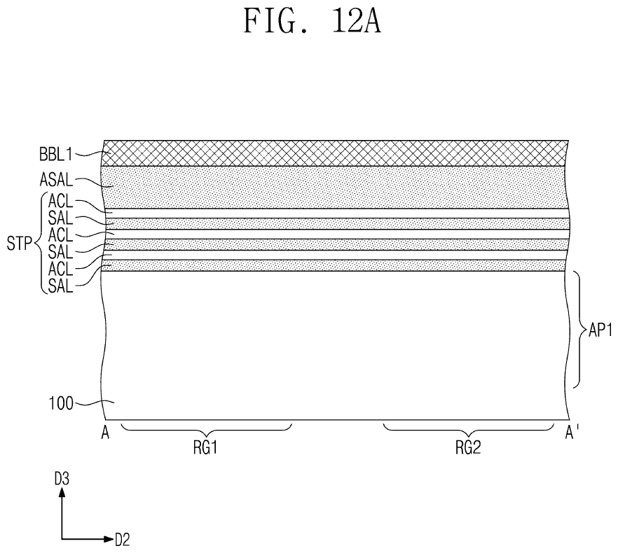

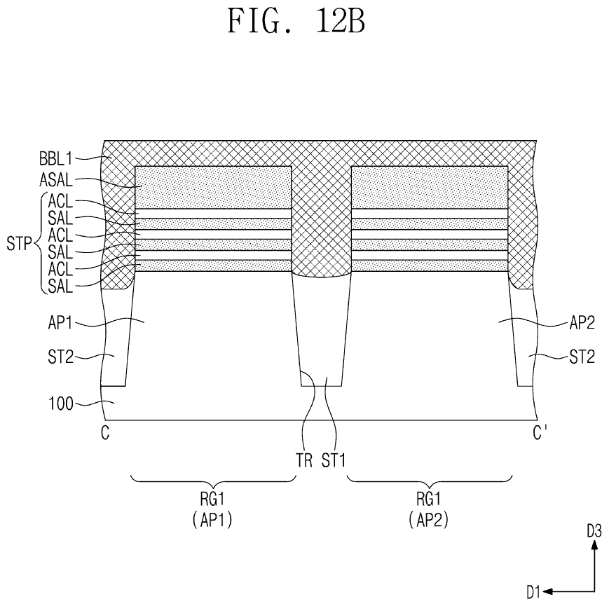

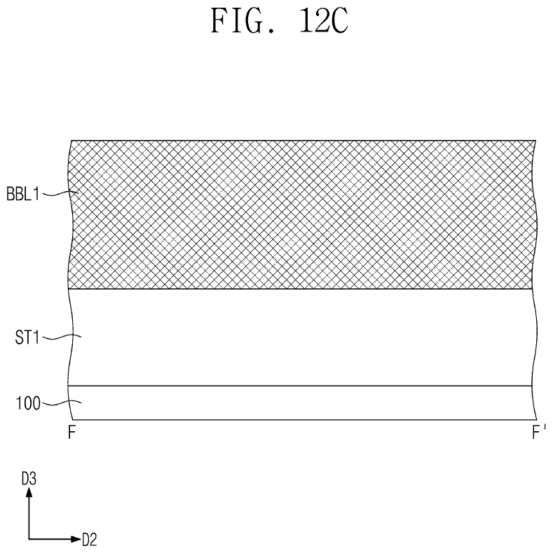

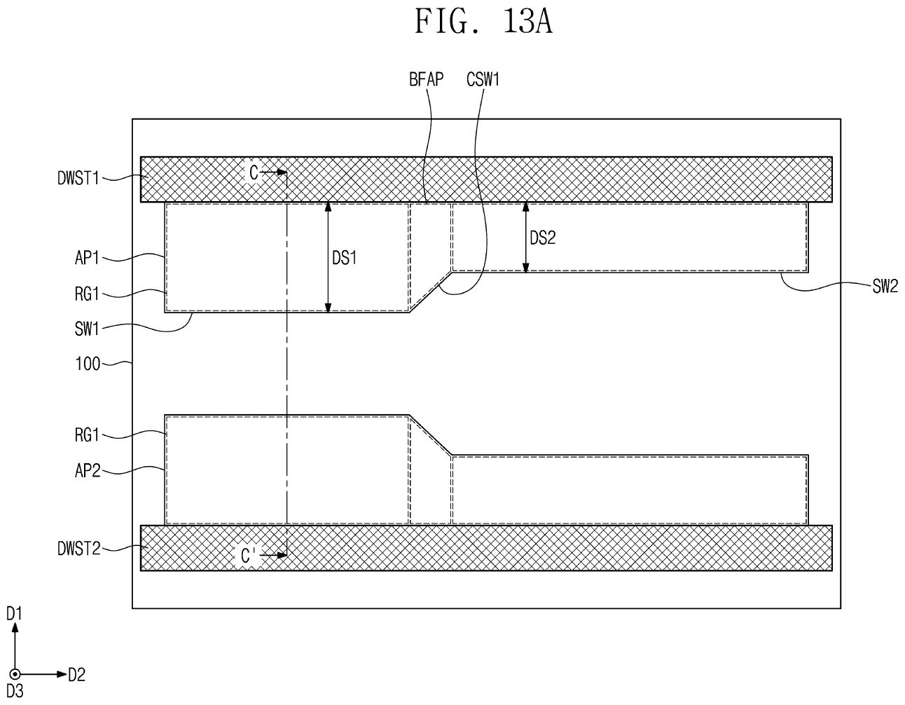

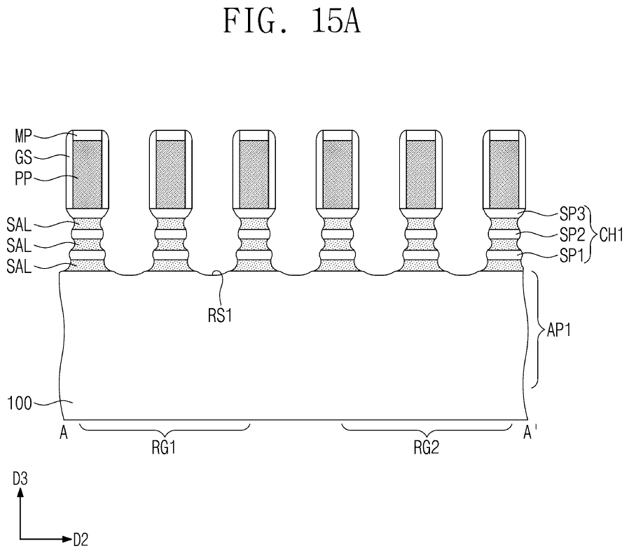

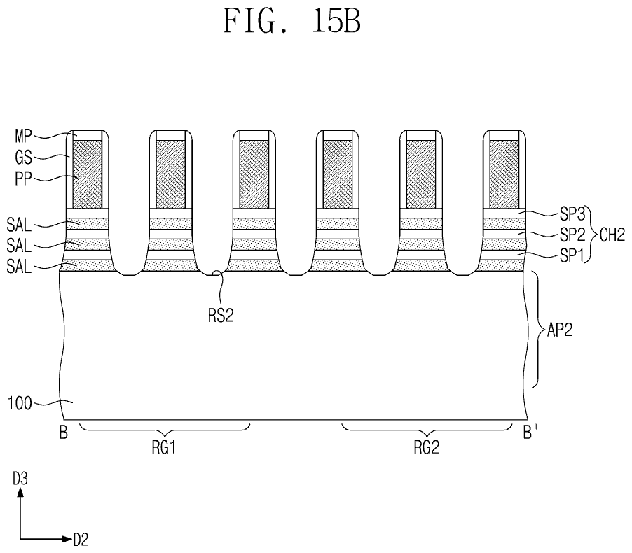

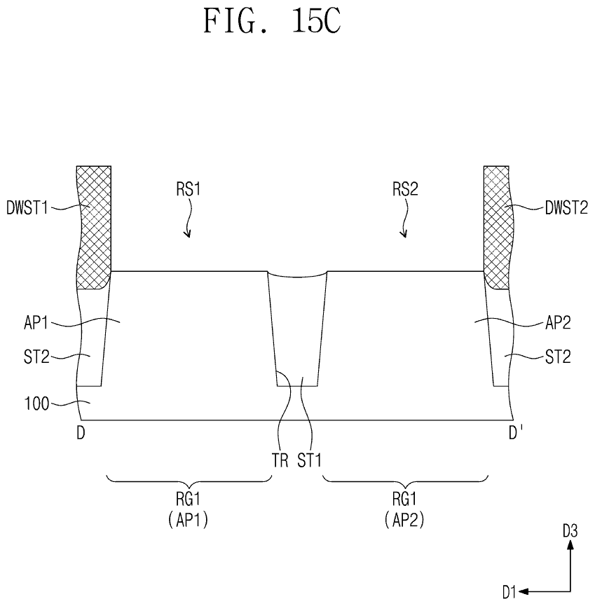

FIGS. 9 to 17E are schematic views for illustrating intermediate processes in an example method of manufacturing a semiconductor device according to embodiments of the inventive concept. In detail, FIGS. 9, 10, and 13A are schematic plan views according to the inventive concept. FIGS. 11A, 12A, 14A, 15A, 16A, and 17A are schematic cross-sectional views corresponding to line A-A′ of FIG. 4. FIGS. 15B, 16B, and 17B are schematic cross-sectional views corresponding to line B-B′ of FIG. 4. FIGS. 11B, 12B, 13B, 14B, and 17C are schematic cross-sectional views corresponding to line C-C′ of FIG. 4. FIGS. 15C, 16C, and 17D are schematic cross-sectional views corresponding to line D-D′ of FIG. 4. FIGS. 12C, 14C and 17E are schematic cross-sectional views corresponding to line F-F′ of FIG. 4.

Referring to FIGS. 9, 10, 11A and 11B, a substrate 100 may be provided. The substrate 100 may be a semiconductor substrate including silicon, germanium, silicon-germanium, or a compound semiconductor substrate. For example, the substrate 100 may be a silicon substrate. Active layers ACL and sacrificial layers SAL may be formed alternately stacked on the substrate 100 in a third direction D3 perpendicular to a surface of the substrate 100. The active layers ACL may include one of silicon (Si), germanium (Ge) and silicon-germanium (SiGe), and the sacrificial layers SAL may include another one of silicon (Si), germanium (Ge) and silicon-germanium (SiGe), although embodiments are not limited thereto.

The sacrificial layer SAL may include a material that may have an etching selectivity with respect to the active layer ACL. For example, the active layers ACL may include silicon (Si), and the sacrificial layers SAL may include silicon-germanium (SiGe). A concentration of germanium (Ge) in each of the sacrificial layers SAL may be about 10 at % to 30 at %.

An additional sacrificial layer ASAL may be formed on the uppermost active layer ACL. The additional sacrificial layer ASAL may be a preliminary sacrificial layer for forming a height of the backbone structure DWST1 and DWST2 in the third direction D3 to be described later to be the same as a height of a gate electrode GE in the third direction D3 to be described later. A thickness of the additional sacrificial layer ASAL in the third direction D3 may be greater than a thickness of each of the alternately stacked sacrificial layers SAL and the active layers ACL in the third direction D3. For example, a thickness of the additional sacrificial layer ASAL may be 2.5 to 4.5 times a thickness of each of the sacrificial layers SAL and the active layers ACL.

The additional sacrificial layers SAL may include silicon-germanium (SiGe). A first hard mask HP1 may be provided on the additional sacrificial layer ASAL. The first hard mask HP1 may be provided on first and second active patterns AP1 and AP2 to be formed. When viewed in a plan view, the first hard mask HP1 may have substantially the same profile as the first and second active patterns AP1 and AP2. For example, at least a portion of the sidewall of the first hard mask HP1 may extend at an acute angle with respect to a second direction D2 parallel to the surface of the substrate 100, such as the first buffer active sidewall CSW1 of FIG. 6.

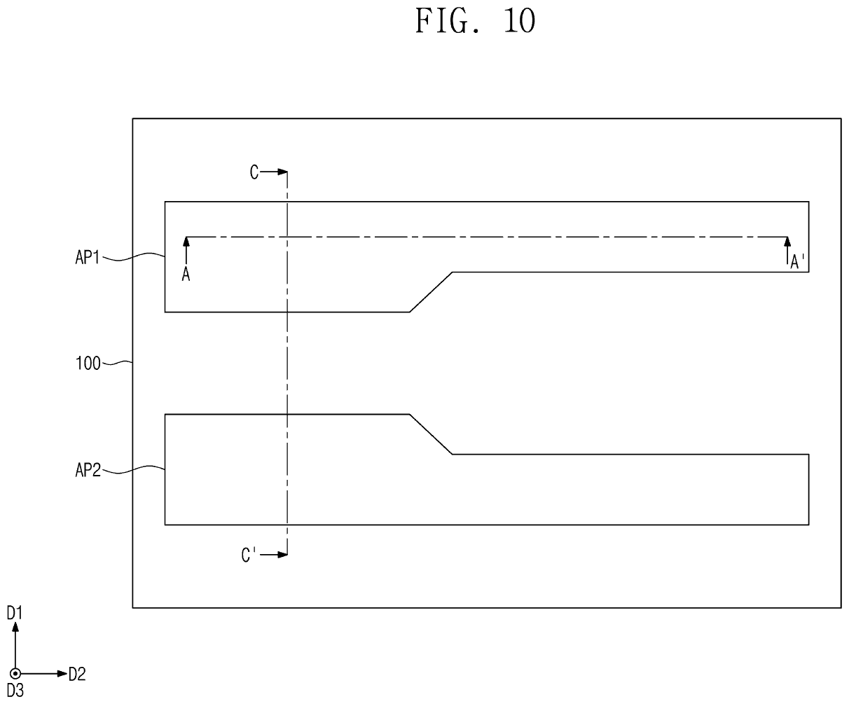

Referring again to FIGS. 10, 11A, and 11B, a patterning process may be performed using the first hard mask HP1 as an etching mask to form a trench TR defining a first active pattern AP1 and a second active pattern AP2. As a result, the first and second active patterns AP1 and AP2 may be formed on the substrate 100, separated from one another by the trench TR in a first direction D1 parallel to the surface of the substrate 100 and intersecting the second direction D2. Widths of the first and second active patterns AP1 and AP2 may be variously changed continuously in the second direction D2.

A stacked pattern STP may be formed on each of the first and second active patterns AP1 and AP2. The stacked pattern STP may include active layers ACL and sacrificial layers SAL that are alternately stacked. The stacked pattern STP may be formed together with the first and second active patterns AP1 and AP2 during the patterning process. The additional sacrificial layer ASAL on the stacked pattern STP may be formed together with the first and second active patterns AP1 and AP2 during the patterning process.

First and second device isolation layers ST1 and ST2 at least partially filling the trench TR may be formed. In detail, an insulating layer covering the first and second active patterns AP1 and AP2, the stacked patterns STP, and the additional sacrificial layers ASAL may be formed on the entire surface of the substrate 100. The insulating layer may be recessed until the additional sacrificial layers ASAL are exposed, thereby forming the first and second device isolation layers ST1 and ST2. Thereafter, the first hard mask HP1 may be removed.

The first and second device isolation layers ST1 and ST2 may include an insulating material, such as a silicon oxide layer. The stacked patterns STP and the additional sacrificial layers ASAL may be exposed over the first and second device isolation layers ST1 and ST2. That is, the stacked patterns STP and the additional sacrificial layers ASAL may protrude vertically over the first and second device isolation layers ST1 and ST2. The term “exposed” (or “expose,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

Referring to FIGS. 12A to 12C, a first backbone layer BBL1 may be formed on the first and second device isolation layers ST1 and ST2, the stacked patterns STP, and the additional sacrificial layers ASAL. The first backbone layer BBL1 may cover upper surfaces of the first and second device isolation layers ST1 and ST2, side surfaces of the stacked patterns STP, and side surfaces and the upper surfaces of the additional sacrificial layers ASAL. The first backbone layer BBL1 may fill a space between the stacked patterns STP and the additional sacrificial layers ASAL. The first backbone layer BBL1 may be formed by performing a chemical vapor deposition (CVD) process or a physical vapor deposition (PVD) process. The first backbone layer BBL1 may include an insulating material. For example, the insulating material may include silicon oxide, silicon nitride, silicon oxynitride, or a combination thereof.

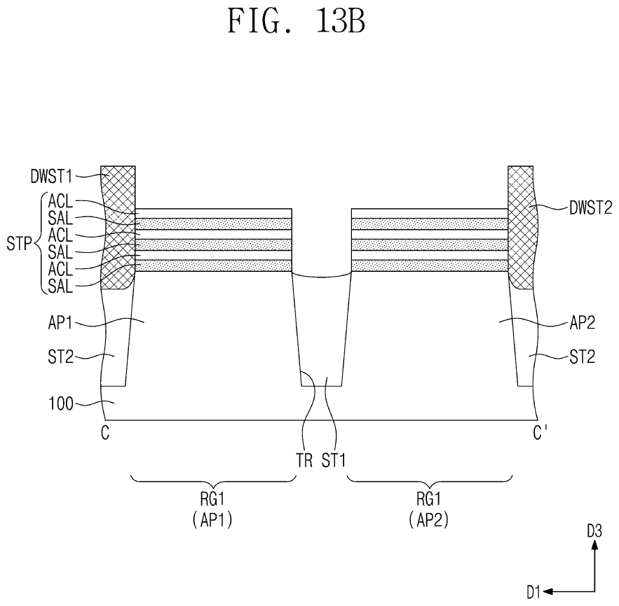

Referring to FIGS. 13A and 13B, the first backbone layer BBL1 (see FIG. 12A) may be planarized until the upper surface of the additional sacrificial layers ASAL is exposed. The planarization of the first backbone layer BBL1 may be performed using a chemical mechanical polishing (CMP) process. During the planarization process, the first backbone layer BBL1 on the additional sacrificial layers ASAL may be completely removed. As a result, first and second backbone structures DWST1 and DWST2 may be formed on sidewalls of the stacked patterns STP. The first backbone structure DWST1 may be in contact with the sidewall of the stacked pattern STP on the first active pattern AP1. The second backbone structure DWST2 may be in contact with the sidewall of the stacked pattern STP on the second active pattern AP2.

The first and second backbone structures DWST1 and DWST2 may be formed on the second device isolation layer ST2. The first and second backbone structures DWST1 and DWST2 may extend from the sidewall of the additional sacrificial layer ASAL to the sidewall of the stacked pattern STP and the upper surface of the second device isolation layer ST2. Upper surfaces of the first and second backbone structures DWST1 and DWST2 may be substantially coplanar with the upper surfaces of the additional sacrificial layers ASAL.

The additional sacrificial layers ASAL may be selectively removed so that only the stacked pattern STP remains on each of the first and second active patterns AP1 and AP2. In detail, by performing an etching process for selectively removing the additional sacrificial layers ASAL, only the additional sacrificial layers ASAL may be removed while leaving the stacked patterns STP and the first and second backbone structures DWST1 and DWST2 intact. The etching process may have a high etching rate for silicon-germanium having a relatively high germanium concentration. For example, the etching process may have a high etching rate for silicon-germanium having a germanium concentration greater than 10 at %.

As only the additional sacrificial layers ASAL are selectively removed, the upper surfaces of the first and second backbone structures DWST1 and DWST2 may be positioned at a higher level in the third direction D3 than the upper surfaces of each of the stacked patterns STP, relative to a surface of the substrate 100 as a reference.

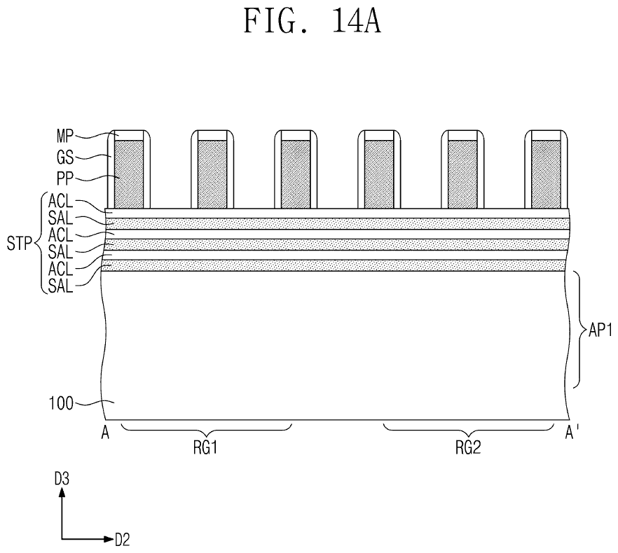

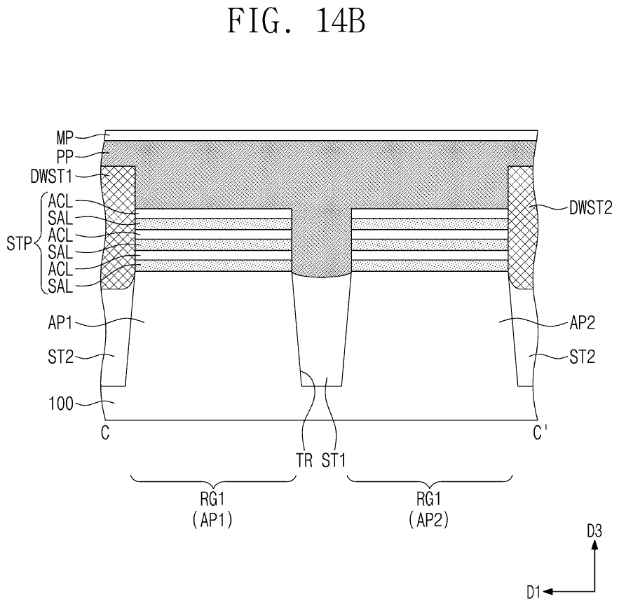

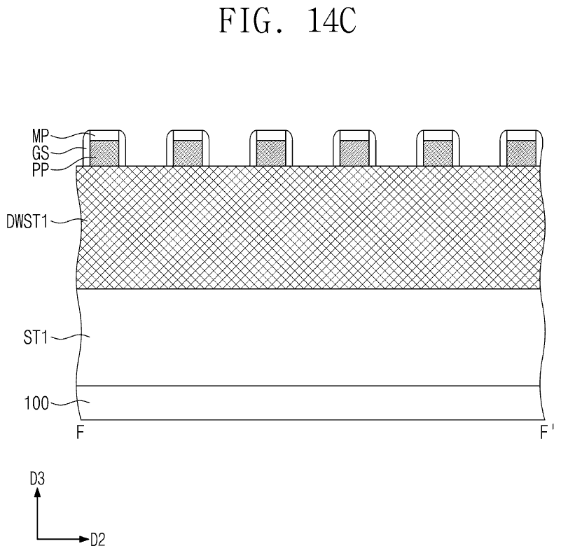

Referring to FIGS. 14A to 14C, sacrificial patterns PP that cross the stacked patterns STP and the first and second backbone structures DWST1 and DWST2 may be formed on the substrate 100. Each of the sacrificial patterns PP may be formed in a line shape or a bar shape (when viewed in plan view) extending in a first direction D1. The sacrificial patterns PP may be arranged in the second direction D2, with adjacent sacrificial patterns PP spaced from each other by a first pitch.

In detail, forming the sacrificial patterns PP may include forming a sacrificial layer on the entire surface of the substrate 100, forming hard mask patterns MP on the sacrificial layer, and patterning the sacrificial layer using the hard mask patterns MP as an etching mask. The sacrificial layer may include polysilicon.

A pair of gate spacers GS may be formed on both sidewalls of each of the sacrificial patterns PP. Forming the gate spacers GS may include conformally forming a gate spacer layer on the entire surface of the substrate 100, and anisotropically etching the gate spacer layer. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. In one embodiment of the inventive concept, the gate spacer GS may be a multi-layer including at least two layers.

Referring to FIGS. 15A to 15C, first recesses RS1 may be formed in the stacked pattern STP (see FIG. 14A) on the first active pattern AP1. Second recesses RS2 may be formed in the stacked pattern STP (see FIG. 14B) on the second active pattern AP2. During the formation of the first and second recesses RS1 and RS2, the first device isolation layer ST1 on both sides of each of the first and second active patterns AP1 and AP2 may be further recessed in the third direction D3.

In detail, the stacked pattern STP on the first active pattern AP1 may be etched using the hard mask patterns MP and the gate spacers GS as etching masks, thereby forming the first recesses RS1. The first recess RS1 may be formed between a pair of sacrificial patterns PP. The first recess RS1 may be formed between adjacent sacrificial patterns PP. The second recesses RS2 in the stacked pattern STP on the second active pattern AP2 may be formed in a similar manner to forming the first recesses RS1.

Referring to FIG. 15C, most of the first and second backbone structures DWST1 and DWST2 may be exposed due to the first recess RS1 and the second recess RS2 formed by recessing the stacked patterns STP. Most of side surfaces of each of the first and second backbone structures DWST1 and DWST2 may be exposed. The first and second backbone structures DWST1 and DWST2 may protrude vertically above the second device isolation layer ST2.

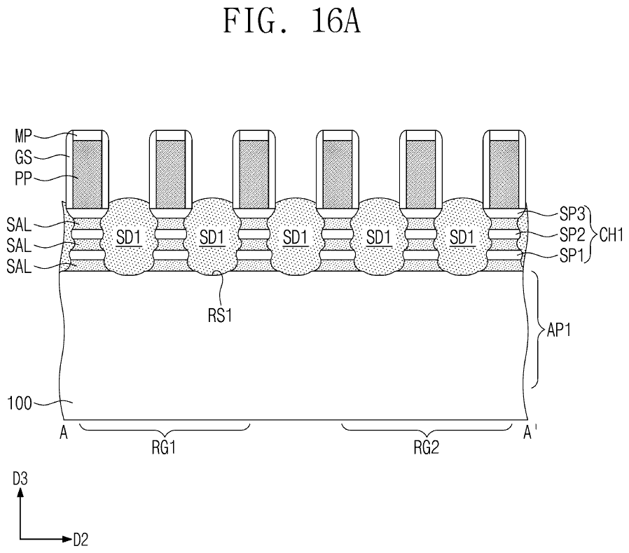

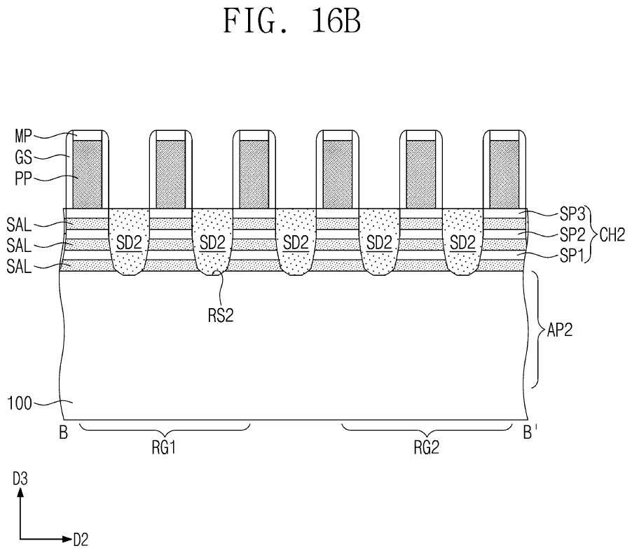

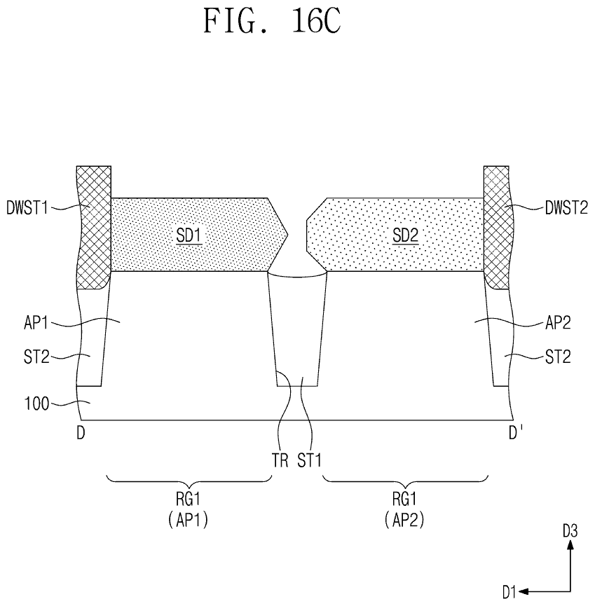

Referring to FIGS. 16A to 16C, first source/drain patterns SD1 may be formed in each of the first recesses RS1. In detail, an SEG (selective epitaxial growth) process may be performed using the inner wall of the first recess RS1 as a seed layer, to form an epitaxial layer filling the first recess RS1. The epitaxial layer may be grown using the sacrificial layers SAL and the substrate 100 exposed by the first recess RS1 as seeds. For example, the SEG process may include a chemical vapor deposition (CVD) process or a molecular beam epitaxy (MBE) process.

In one embodiment of the inventive concept, the first source/drain pattern SD1 may include a semiconductor device (e.g., SiGe) having a lattice constant greater than a lattice constant of a semiconductor device of the substrate 100. While the first source/drain pattern SD1 is formed, impurities (e.g., boron, gallium, or indium) that causes the first source/drain pattern SD1 to have a p-type conductivity may be implanted in-situ. As another example, impurities may be implanted into the first source/drain pattern SD1 after the first source/drain pattern SD1 is formed.

Second source/drain patterns SD2 may be formed in each of the second recesses RS2. In detail, an SEG process may be performed using the inner wall of the second recess RS2 as a seed layer to form the second source/drain pattern SD2.

In one embodiment of the inventive concept, the second source/drain patterns SD2 may include the same semiconductor device (e.g., Si) as the substrate 100. While the second source/drain patterns SD2 are formed, impurities (e.g., phosphorus, arsenic, or antimony) that causes the second source/drain patterns SD2 to have an n-type conductivity may be implanted in-situ. As another example, impurities may be injected into the second source/drain patterns SD2 after the second source/drain patterns SD2 are formed.

In another embodiment, depending on whether each of the first and second active patterns AP1 and AP2 is an NMOSFET region or a PMOSFET region, the types of impurities included in the first and second source/drain patterns SD1 and SD2 may be variously changed. For example, when the first and second active patterns AP1 and AP2 are an NMOSFET region, impurities (e.g., phosphorus, arsenic, or antimony) that causes the first and second source/drain patterns SD1 and SD2 to have an n-type may be implanted in-situ. Again, for example, when the first and second active patterns AP1 and AP2 are a PMOSFET region, impurities (e.g., boron, gallium, or indium) that causes the first and second source/drain patterns SD1 and SD2 to have a p-type may be implanted in-situ.

Referring to FIG. 16C, one of the side surfaces of each of the first and second source/drain patterns SD1 and SD2 may be in direct contact with the first and second backbone structures DWST1 and DWST2. For example, a side surface of the first source/drain pattern SD1 may be in direct contact with the first backbone structure DWST1. A side surface of the second source/drain pattern SD2 may be in direct contact with the second backbone structure DWST2. An upper surface of each of the first and second source/drain patterns SD1 and SD2 may be positioned at a lower level in the third direction D3 than the upper surfaces of the first and second backbone structures DWST1 and DWST2, relative to the surface of the substrate 100.

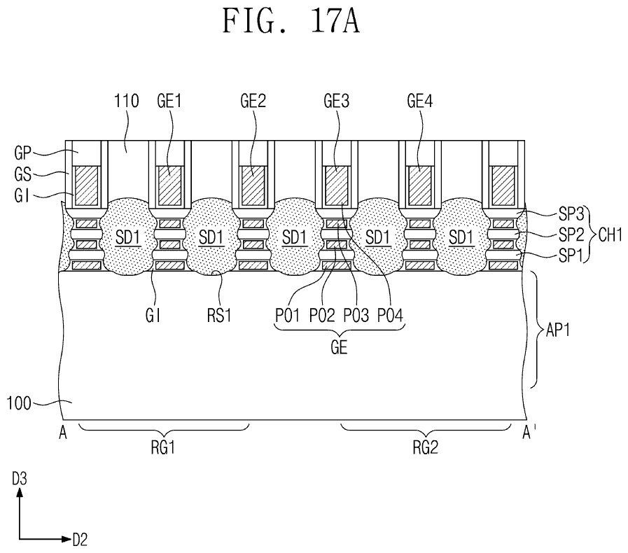

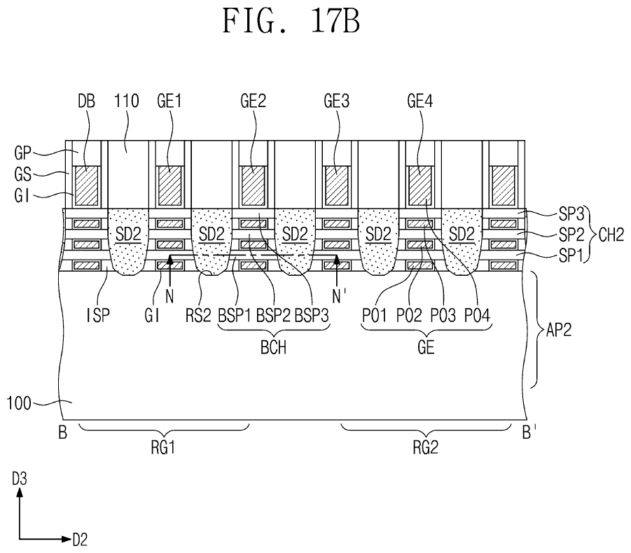

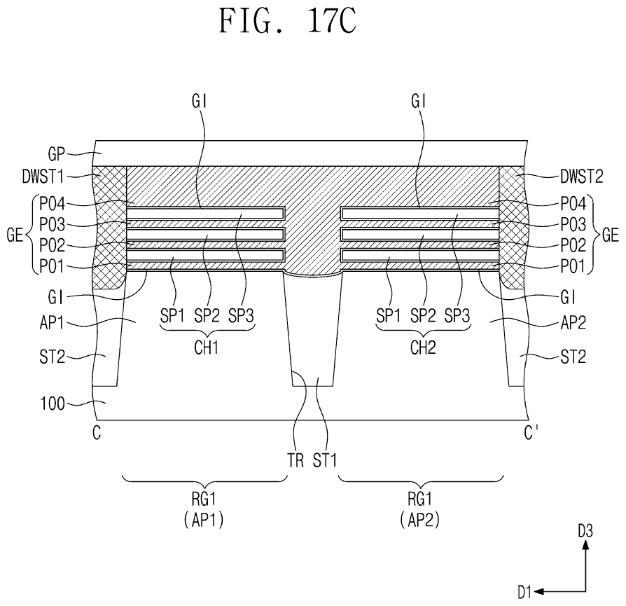

Referring to FIGS. 17A to 17E, a first interlayer insulating layer 110 covering the first and second source/drain patterns SD1 and SD2, the hard mask patterns MP (see FIGS. 16A and 16B), and the gate spacers GS may be formed. For example, the first interlayer insulating layer 110 may include a silicon oxide layer. The first interlayer insulating layer 110 may cover the first and second source/drain patterns SD1 and SD2 and the first and second backbone structures DWST1 and DWST2.

The first interlayer insulating layer 110 may be planarized until upper surfaces of the sacrificial patterns PP are exposed. The planarization of the first interlayer insulating layer 110 may be performed, for example, using an etch back or chemical mechanical polishing (CMP) process. During the above planarization process, all of the hard mask patterns MP may be removed. As a result, the upper surface of the first interlayer insulating layer 110 may be coplanar with the upper surfaces of the sacrificial patterns PP and the upper surfaces of the gate spacers GS in the third direction D3.

The exposed sacrificial patterns PP may be selectively removed. The sacrificial patterns PP may be removed to form an outer region exposing first and second channel patterns CH1 and CH2, respectively. Removing the sacrificial patterns PP may include wet etching using an etchant that selectively etches polysilicon.

The sacrificial layers SAL exposed through the outer region may be selectively removed, thereby forming inner regions. In detail, an etching process that selectively etches the sacrificial layers SAL may be performed to remove only the sacrificial layers SAL while leaving the first to third semiconductor patterns SP1, SP2, and SP3 intact. The etching process may have a high etching rate for silicon-germanium having a relatively high germanium concentration. For example, the etching process may have a high etching rate for silicon-germanium having a germanium concentration greater than 10 at %.

During the etching process, the sacrificial layers SAL on the first and second active regions AR1 and AR2 may be removed. The etching process may be wet etching. The etching material used in the etching process may quickly remove the sacrificial layer SAL having a relatively high germanium concentration.

As the sacrificial layers SAL are selectively removed, only the first to third semiconductor patterns SP1, SP2, and SP3 stacked on each of the first and second active patterns AP1 and AP2 may remain. The inner regions may be formed through the regions where the sacrificial layers SAL are removed, respectively. In detail, a first inner region may be formed between the active pattern AP1 or AP2 and the first semiconductor pattern SP1, a second inner region may be formed between the first semiconductor pattern SP1 and the second semiconductor pattern SP2, and a third inner region may be formed between the second semiconductor pattern SP2 and the third semiconductor pattern SP3.

A gate insulating layer GI may be formed on the exposed first to third semiconductor patterns SP1, SP2, and SP3. The gate insulating layer GI may be formed to surround each of the first to third semiconductor patterns SP1, SP2, and SP3. That is, the gate insulating layer GI may be formed on an upper surface, a side surface, and a bottom surface of each of the first to third semiconductor patterns SP1, SP2, and SP3. The gate insulating layer GI may be omitted between the first to third semiconductor patterns SP1, SP2, and SP3 and the first and second backbone structures DWST1 and DWST2. The gate insulating layer GI may be formed in the first to third inner regions. The gate insulating layer GI may be formed in the outer region. The gate insulating layer GI may be formed on the first device isolation layer ST1 and the active patterns AP1 and AP2.

A gate electrode GE may be formed on the gate insulating layer GI. In detail, the gate electrode GE may be formed on a high-k dielectric layer. That is, a high-k dielectric layer may be formed on the gate insulating layer GI, and the gate electrode GE may be formed on the high-k dielectric layer.

The gate electrode GE may include first to third inner electrodes PO1, PO2, and PO3 formed in the first to third inner regions, respectively, and an outer electrode PO4 formed in the outer region. The gate electrode GE may be recessed to reduce a height thereof. A gate capping pattern GP may be formed on the recessed gate electrode GE. A second interlayer insulating layer 120 may be formed on the first interlayer insulating layer 110. The second interlayer insulating layer 120 may include a silicon oxide layer.

Referring to FIGS. 4, 5A to 5F, active contacts AC may be formed that are electrically connected to the first and second source/drain patterns SD1 and SD2 by penetrating (i.e., extending in) the second interlayer insulating layer 120 and the first interlayer insulating layer 110. A gate contact GC electrically connected to a gate electrode GE may be formed by penetrating the second interlayer insulating layer 120 and the gate capping pattern GP.

Forming each active contact AC and gate contact GC may include forming a barrier pattern BM and forming a conductive pattern FM on the barrier pattern BM. The barrier pattern BM may be formed conformally and may include a metal layer/metal nitride layer, although embodiments are not limited thereto. The conductive pattern FM may include a low-resistance metal. Separation structures DB may be formed on a boundary of the single height cell SHC, respectively. The separation structure DB may extend from the second interlayer insulating layer 120 through the gate electrode GE into the interior of the active pattern AP1 and AP2. The separation structure DB may include an insulating material such as a silicon oxide layer or a silicon nitride layer. As another example, the separation structure DB may include a metal material.

A third interlayer insulating layer 130 may be formed on the active contacts AC and the gate contacts GC. A first metal layer M1 may be formed in the third interlayer insulating layer 130. The first metal layer M1 may include a first wiring line M1_I electrically connected to at least one of the active contacts AC and the gate contacts GC. A fourth interlayer insulating layer 140 may be formed on the third interlayer insulating layer 130. A second metal layer M2 may be formed in the fourth interlayer insulating layer 140.

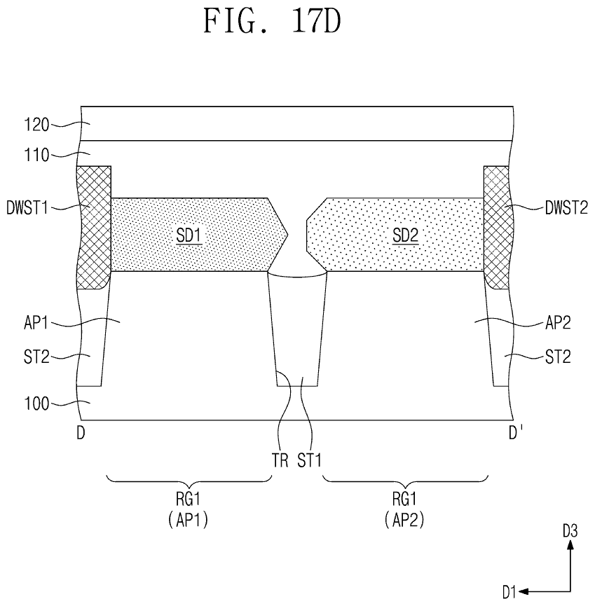

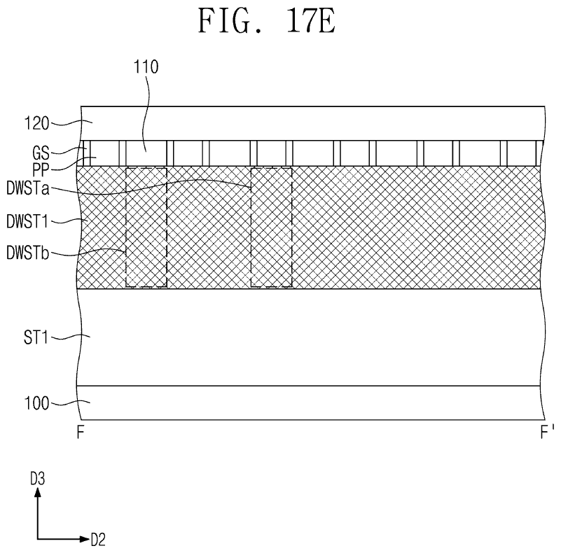

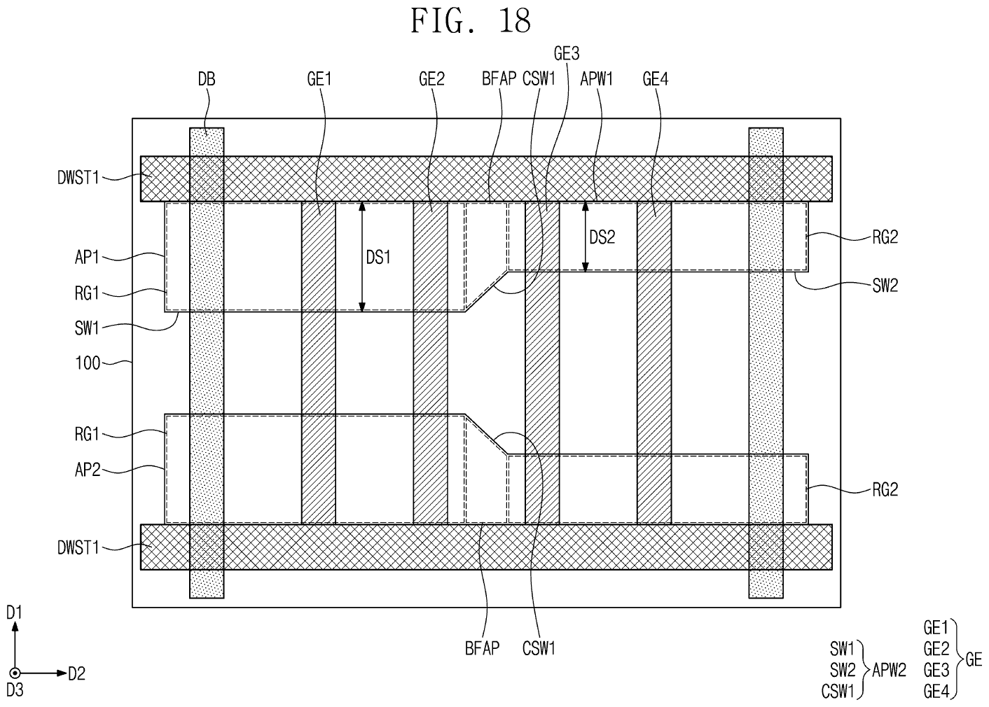

In the embodiments of the inventive concept described below, a detailed description of technical features, elements and/or structures that are repeated with those features, elements and/or structures that were previously described with reference to FIGS. 6 and 7 will be omitted, and differences will be described in detail. FIGS. 18 and 19 are schematic plan views for illustrating a semiconductor device according to another embodiment of the inventive concept.

Referring to FIGS. 18 and 19, a buffer active pattern BFAP may be provided between gate electrodes GE adjacent to each other in the second direction D2. The buffer active pattern BFAP may not vertically (i.e., in the third direction D3) overlap the gate electrodes GE. For example, the buffer active pattern BFAP may be provided between a second gate electrode GE2 and a third gate electrode GE3.

A first source/drain pattern SD1 or a second source/drain pattern SD2 may be provided on the buffer active pattern BFAP. A width in the first direction D1 of the first active pattern AP1 on the buffer active pattern BFAP may be gradually changed. Accordingly, a width in the first direction D1 of the first or second source/drain pattern SD1 or SD2 on the buffer active pattern BFAP may be changed as the buffer active pattern BFAP extends in the second direction D2. Referring back to FIG. 19, as described with reference to FIG. 8A, widths in the first direction D1 of the first and second backbone structures DWST1 and DWST2 may be variously changed as the first and second backbone structures DWST1 and DWST2 extend in the second direction D2.

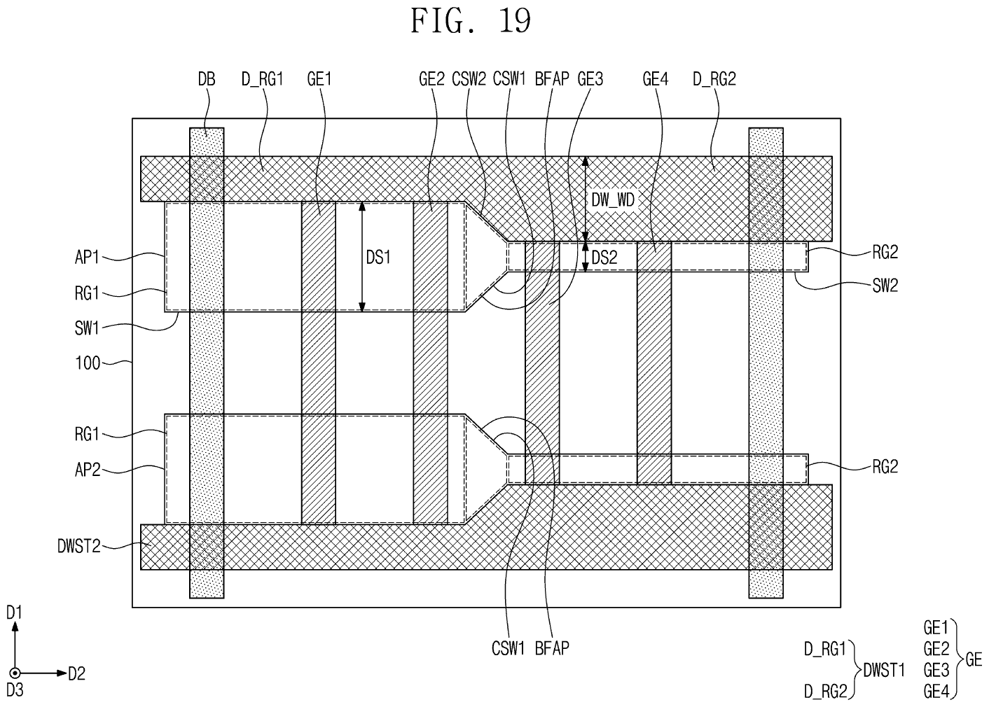

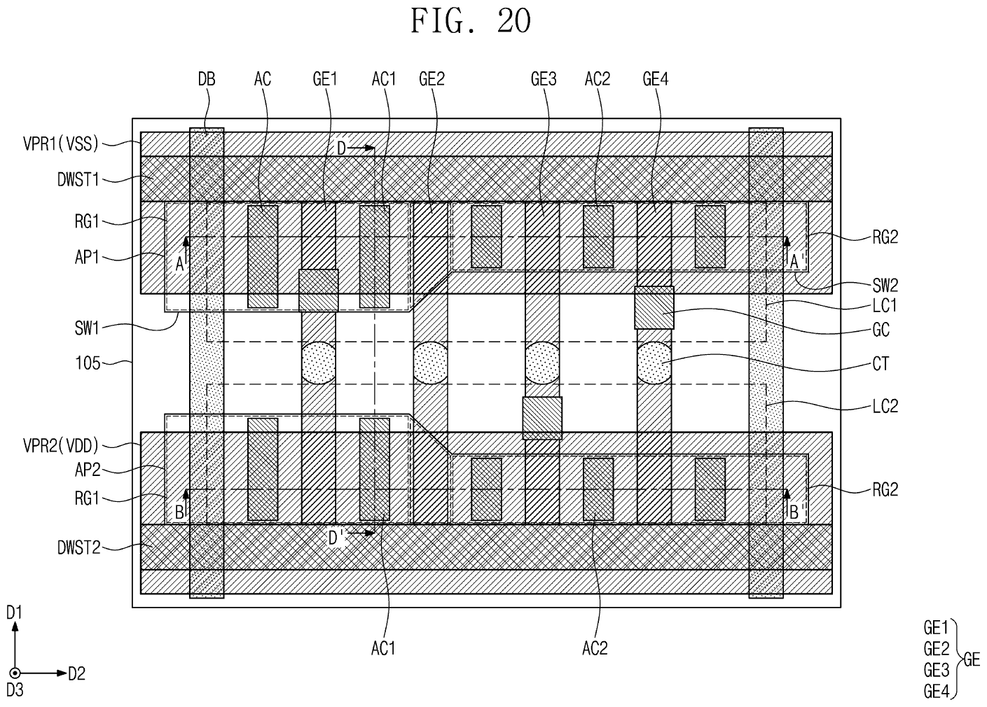

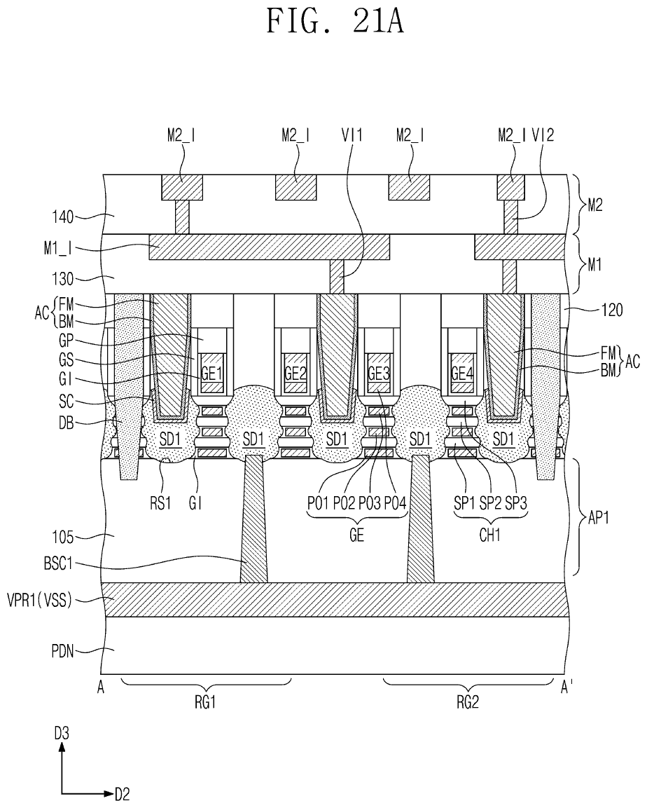

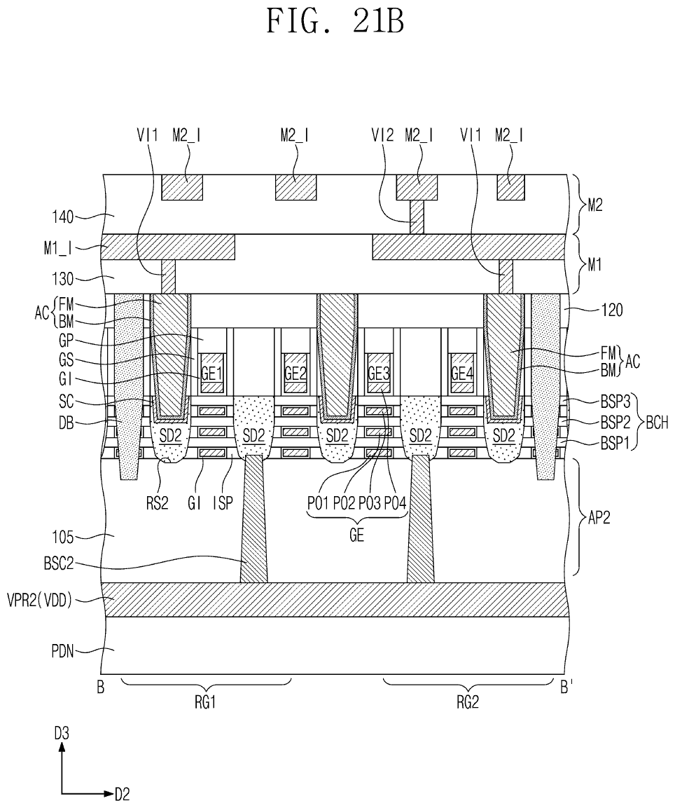

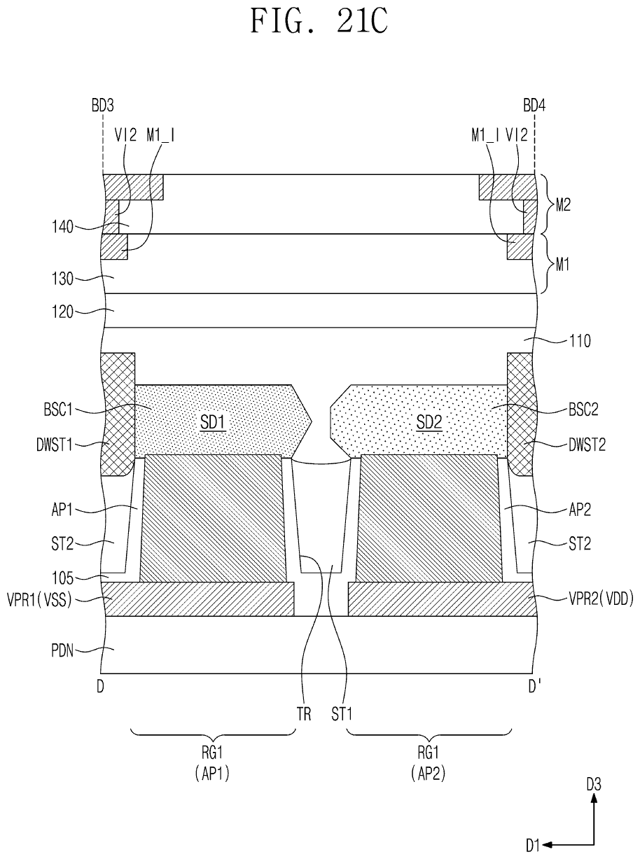

FIG. 20 is a schematic plan view for illustrating another embodiment of the inventive concept. FIGS. 21A to 21C are schematic cross-sectional views illustrating a semiconductor device according to another embodiment of the inventive concept. In detail, FIG. 21A is a schematic cross-sectional view taken along line A-A′ of FIG. 20. FIG. 21B is a schematic cross-sectional view taken along line B-B′ of FIG. 20. FIG. 21C is a schematic cross-sectional view taken along line D-D′ of FIG. 20.

Referring to FIG. 20 and FIGS. 21A to 21C, a substrate 105 may include a silicon-based insulating layer. That is, the substrate 105 may be an insulating substrate. The substrate 105 may include a silicon oxide layer, a silicon nitride layer, or a silicon oxynitride layer.

First and second lower power lines VPR1 and VPR2 may be provided on the lower portion of the substrate 105. The first and second lower power lines VPR1 and VPR2 may extend parallel to each other in a second direction D2. The first lower power line VPR1 may vertically overlap a first active pattern AP1. The second lower power line VPR2 may vertically overlap a second active pattern AP2.

The first and second lower power lines VPR1 and VPR2 may include at least one material selected from the group consisting of copper, molybdenum, tungsten, and ruthenium. A bottom surface of each of the first and second lower power lines VPR1 and VPR2 may be coplanar with a bottom surface of the substrate 105.

A power transmission network layer PDN may be provided on the bottom surface of the substrate 105. The power transmission network layer PDN may include a plurality of lower wiring lines electrically connected to the first and second lower power lines VPR1 and VPR2. For example, the power transmission network layer PDN may include a wiring network for applying a source voltage VSS to the first lower power line VPR1. The power transmission network layer PDN may include a wiring network for applying a drain voltage VDD to the second lower power line VPR2.

A first backside contact BSC1 may be provided that extends vertically from the first lower power line VPR1 to the first source/drain pattern SD1 through the substrate 105. A second backside contact BSC2 may be provided that extends vertically from the second lower power line VPR2 to the second source/drain pattern SD2 through the substrate 105. Widths of the first and second backside contacts BSC1 and BSC2 in the second direction D2 may decrease from the bottom surface of the substrate 105 in the vertical direction D3.

The first backside contact BSC1 may have a conductive pillar shape that extends vertically (i.e., in the third direction D3) and electrically connects the first lower power line VPR1 and the first source/drain pattern SD1. The source voltage VSS may be applied to the first source/drain pattern SD1 through the first backside contact BSC1.

The second backside contact BSC2 may have a conductive pillar shape that extends vertically and electrically connects the second lower power line VPR2 and the second source/drain pattern SD2. A drain voltage VDD may be applied to the second source/drain pattern SD2 through the second backside contact BSC2.

A power line for supplying power to the single height cell SHC may be embedded in the substrate 105 in a form of the lower power line VPR1 and VPR2. As a result, the power line may be omitted in the first metal layer M1. First wiring lines M1_I for signal transmission may be disposed in the first metal layer M1.

In the semiconductor device according to the inventive concept, the backbone structure may be formed on the one side of the active pattern, thereby reducing the area occupied by the unit cell constituting the logic device on the substrate. That is, the number of unit cells formed on the substrate may be increased, thereby improving the integration of the semiconductor device.

In the semiconductor device according to the inventive concept, the width of the active pattern may be variously changed. The one sidewall of the active pattern may be in direct contact with the backbone structure, and the other sidewall may be spaced apart from the backbone structure. In this case, the distance between the other sidewall of the active pattern and the backbone structure may be variously changed. The sidewall of the active pattern may be obliquely formed, and thus the width of the active pattern may be variously changed. As a result, the electrical characteristics and reliability of the semiconductor device may be improved.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor device, comprising:
a first active pattern on a substrate;
channel patterns on the first active pattern;
a gate electrode extending in a first direction parallel to a surface of the substrate on the first active pattern; and
a backbone structure extending in a second direction parallel to the surface of the substrate and intersecting the first direction,
wherein the first active pattern includes a first region and a second region spaced apart from each other in the second direction,
wherein the first active pattern includes:
a first active sidewall in direct contact with the backbone structure; and
a second active sidewall spaced apart from the first active sidewall in the first direction, and
wherein a distance between the first active sidewall and the second active sidewall in the first direction varies as the first active pattern extends in the second direction from the first region toward the second region.

2. The semiconductor device of claim 1, wherein the first region includes a first sidewall extending in the second direction,
wherein the second region includes a second sidewall extending in the second direction, and
wherein the second active sidewall includes a buffer active sidewall connecting the first sidewall and the second sidewall.

3. The semiconductor device of claim 2, wherein the first sidewall and the buffer active sidewall form a first angle,
wherein the second sidewall and the buffer active sidewall form a second angle, and
wherein the first angle is about 91° to 179°.

4. The semiconductor device of claim 3, wherein the second angle is about 181° to 269°.

5. The semiconductor device of claim 2, wherein the first region has a first distance in the first direction between the backbone structure and the first sidewall,
wherein the second region has a second distance in the first direction between the backbone structure and the second sidewall, and
wherein the buffer active sidewall is configured to transition from the first distance to the second distance as the second active sidewall extends in the second direction between the first region and the second region.

6. The semiconductor device of claim 1, wherein the channel patterns include a first channel region and a second channel region spaced apart in the second direction,
wherein each of the channel patterns includes:
a first channel sidewall in contact with the backbone structure; and
a second channel sidewall spaced apart from the first channel sidewall in the first direction, and
wherein a distance between the first channel sidewall and the second channel sidewall in the first direction varies from the first channel region toward the second channel region.

7. The semiconductor device of claim 6, wherein the first channel region has a first width in the first direction,
wherein the second channel region has a second width in the first direction, and
wherein a width of the channel patterns in the first direction decreases or increases from the first channel region toward the second channel region.

8. The semiconductor device of claim 1, further comprising source/drain patterns electrically connected to the channel patterns,
wherein the source/drain patterns include a first source/drain pattern on the first region and a second source/drain pattern on the second region, and
wherein a width of the first source/drain pattern in the first direction is different from a width of the second source/drain pattern in the first direction.

9. The semiconductor device of claim 1, wherein the backbone structure includes:
a first backbone region in contact with the first region; and
a second backbone region in contact with the second region, and
wherein a width of the backbone structure in the first direction varies as the backbone structure extends in the second direction from the first backbone region toward the second backbone region.

10. The semiconductor device of claim 1, further comprising:
a lower power line in a lower portion of the substrate;
a power transmission network layer below the lower power line;
source/drain patterns electrically connected to the channel patterns; and
a backside contact extending in the substrate and electrically connecting the lower power line and the source/drain pattern to each other.

11. A semiconductor device, comprising:
a first active pattern on a substrate;
channel patterns on the first active pattern;
source/drain patterns electrically connected to the channel patterns;
a gate electrode extending in a first direction parallel to a surface of the substrate on the first active pattern; and
a backbone structure extending in a second direction parallel to the surface of the substrate and intersecting the first direction,
wherein the first active pattern includes a first region and a second region spaced apart from each other in the second direction,
wherein the first active pattern includes:
a first active sidewall in direct contact with the backbone structure; and
a second active sidewall spaced apart from the first active sidewall in the first direction,
wherein the second active sidewall includes a first sidewall of the first region, a second sidewall of the second region, and a buffer active sidewall connecting the first sidewall and the second sidewall,
wherein a first distance is a distance between the backbone structure and the first sidewall in the first direction,
wherein a second distance is a distance between the backbone structure and the second sidewall in the first direction, and
wherein the buffer active sidewall is configured to transition from the first distance to the second distance as the buffer active sidewall extends in the second direction between the first region and the second region.

12. The semiconductor device of claim 11, wherein the first distance is greater than the second distance.

13. The semiconductor device of claim 11, wherein the first distance is smaller than the second distance.

14. The semiconductor device of claim 11, wherein the first sidewall and the buffer active sidewall form a first angle,
wherein the second sidewall and the buffer active sidewall form a second angle,
wherein the first angle is about 91° to 179°, and
wherein the second angle is about 181° to 269°.

15. The semiconductor device of claim 11, wherein the backbone structure includes:
a first backbone region in contact with the first region; and
a second backbone region in contact with the second region, and
wherein a width of the backbone structure in the first direction varies as the backbone structure extends from the first backbone region toward the second backbone region.

16. A semiconductor device, comprising:
a substrate including an active pattern;
a device isolation layer defining the active pattern;
source/drain patterns on the active pattern;
channel patterns electrically connected to the source/drain patterns on the active pattern, each of the channel patterns including a plurality of semiconductor patterns vertically stacked and spaced apart from each other;
gate electrodes on the channel patterns, respectively, the gate electrodes extending parallel to each other in a first direction parallel to a surface of the substrate;
a backbone structure extending in a second direction parallel to the surface of the substrate and intersecting the first direction on the device isolation layer;
a gate insulating layer between each of the gate electrodes and each of the channel patterns;
a gate spacer on a sidewall of each of the gate electrodes;
a gate capping pattern on an upper surface of each of the gate electrodes;
an interlayer insulating layer on the gate capping pattern;
active contacts extending in the interlayer insulating layer and electrically connected to the source/drain patterns, respectively;
gate contacts extending in the interlayer insulating layer and the gate capping pattern and electrically connected to the gate electrodes, respectively; and
a first metal layer on the interlayer insulating layer, the first metal layer including first lines electrically connected to the active contacts and the gate contacts, respectively,
wherein the active pattern includes a first region and a second region spaced apart from each other in the second direction,
wherein the active pattern includes:
a first active sidewall in direct contact with the backbone structure; and
a second active sidewall spaced apart from the first active sidewall in the first direction, and
wherein a distance between the first active sidewall and the second active sidewall in the first direction varies as the active pattern extends in the second direction from the first region toward the second region.

17. The semiconductor device of claim 16, wherein the second active sidewall includes a first sidewall of the first region, a second sidewall of the second region, and a buffer active sidewall connecting the first sidewall and the second side wall,
wherein a first distance is a distance in the first direction between the backbone structure and the first sidewall,
wherein a second distance is a distance in the first direction between the backbone structure and the second sidewall, and
wherein the buffer active sidewall is configured to transition from the first distance to the second distance as the buffer active sidewall extends in the second direction between the first region and the second region.

18. The semiconductor device of claim 16, wherein the channel patterns include a first channel region and a second channel region spaced apart in the second direction,
wherein each of the channel patterns includes:
a first channel sidewall in contact with the backbone structure; and
a second channel sidewall spaced apart from the first channel sidewall in the first direction, and
wherein a distance between the first channel sidewall and the second channel sidewall in the first direction varies as the channel pattern extends in the second direction from the first channel region toward the second channel region.

19. The semiconductor device of claim 16, wherein the source/drain patterns include a first source/drain pattern on the first region and a second source/drain pattern on the second region, and
wherein a width of the first source/drain pattern in the first direction is different from a width of the second source/drain pattern in the first direction.

20. The semiconductor device of claim 16, wherein the backbone structure includes:
a first backbone region in contact with the first region; and
a second backbone region in contact with the second region, and
wherein a width of the backbone structure in the first direction varies as the backbone structure extends from the first backbone region toward the second backbone region.
